(19) United States
(12) Patent Application Publication
(10) Pub. No.: US 2025/0043173 A1
(43) Pub. Date: Feb. 6, 2025

(54) COMPOUND, ORGANIC ELECTRONIC COMPONENT, LIGHT-EMITTING LAYER, AND ORGANIC LIGHT-EMITTING DIODE OR DEVICE INCLUDING SAME

(71) Applicants: Yonsei University, University - Industry Foundation (UIF), Seoul (KR); Ewha University - Industry Collaboration Foundation, Seoul (KR)

(72) Inventors: Youngmin You, Seoul (KR); Byung Hak Jhun, Seoul (KR); Sreenivas Avula, Seoul (KR)

(21) Appl. No.: 18/783,640

(22) Filed: Jul. 25, 2024

(30) Foreign Application Priority Data
Jul. 25, 2023 (KR) 10-2023-0096937

(51) Int. Cl. C09K 11/06; H10K 50/11; H10K 85/30

(52) U.S. Cl. CPC C09K 11/06; H10K 50/11; H10K 85/371; C09K 2211/188

(57) ABSTRACT

A compound represented by Chemical Formula 1, an organic electronic component or a light-emitting layer including same, an OLED including the light-emitting layer, and a device comprising the OLED are provided:

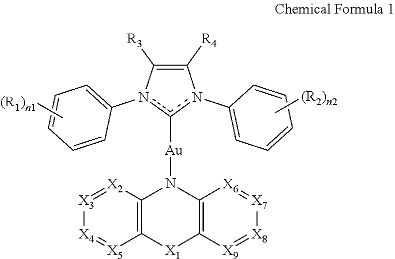

wherein in Chemical Formula 1, R₁ to R₄, n1 and n2, and X₁ to X₉ are the same as defined in the specification.

### CROSS REFERENCE TO RELATED APPLICATIONS

This application claims priority to Korean Patent Application No. 10-2023-0096937 filed in the Korean Intellectual Property Office on Jul. 25, 2023, and all the benefits arising therefrom under 35 U.S.C. § 119, the contents of which are herein incorporated by reference in their entirety.

### BACKGROUND

### 1. Field

A Compound, an organic electronic component, a light-emitting layer, and organic light-emitting diode or device including same are disclosed.

This application has been derived from a work supported by a grant from the Samsung Research Funding Center for Future Technology (SRFC-MA1301-51).

### 2. Description of the Related Art

Two-coordinate complexes of coinage metals, such as, for example, gold (Au), silver (Ag), copper (Cu), etc., have emerged as promising emitters for highly efficient organic light-emitting diodes (OLED). The advances of organic light-emitting devices (OLED) have been driven by the development of emitting molecules capable of harvesting all the electrogenerated excitons. In particular, organic molecules exhibiting thermally activated delayed fluorescence (TADF) enable high-efficiency electroluminescence across a broad range of visible regions. However, incorporating organic TADF emitters into OLEDs presents challenges such as the moderate operational stability and a decline in electroluminescence efficiencies at high brightness, primarily due to slow exciton conversion.

Recently, two-coordinate complexes involving coinage metals, such as, Cu(I), Ag(I), and Au(I), have emerged as promising alternatives to conventional organic emitters. Benefiting from the strong spin-orbit coupling provided by the metals and the effective separation of molecular orbitals during the electron transition process, these metal complexes exhibit TADF or phosphorescence through fast exciton harvesting. Importantly, this exciton harvest does not compromise the quantum yield for photoluminescence, facilitating high-brightness emission. As a result, coinage metal complexes are capable of uniquely combining the advantages of both organic TADF molecules and phosphorescent complexes of late transition metals, such as Ir(III) and Pt(II). Further, the coinage metals are more abundant on earth than the rare earth metals such as iridium (III), platinum (II), etc., and are also cheaper per weight. Accordingly, the emitters containing coinage metals are economically more advantageous than those containing rare earth metals.

Therefore, there is a need to develop emitters containing coinage metals that can emit light in various wavelengths.

### SUMMARY

An embodiment provides a novel compound including a gold (Au) complex that can emit light in various wavelength ranges.

Another embodiment provides an organic electronic component including the novel compound.

Still another embodiment provides a light-emitting layer including the novel compound.

Fur still another embodiment provides an organic light-emitting diode (OLED) including the light-emitting layer.

Fur still another embodiment provides a device including the OLED.

The novel compound according to an embodiment is represented by Chemical Formula 1:

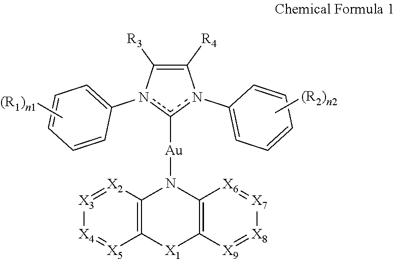

wherein in Chemical Formula 1,
R₁ and R₂ are, each independently, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, a substituted or unsubstituted C2 to C30 heterocyclic group, a substituted or unsubstituted C1 to C30 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, or a substituted or unsubstituted C2 to C30 heterocyclic group), a nitro group, a halogen atom, or a combination thereof,
n1 and n2 are, each independently, an integer of 0 to 5,
R₃ and R₄ are, each independently, hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, a substituted or unsubstituted C2 to C30 heterocyclic group, a substituted or unsubstituted C1 to C30 alkoxy group, a substituted or unsubstituted amino group, a substituted or unsubstituted silyl group, a cyano group, a carboxyl group, —C(═O)R^{a}(wherein, R^{a} is hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, or a substituted or unsubstituted C2 to C30 heterocyclic group), a nitro group, a halogen atom, or a combination thereof, or optionally, the groups of R₃ and R₄ are linked to each other to form a ring,
X₁ is single bond, —(CRR′)ₙ₃—, —C(R)═C(R′)—, —C≡C—, —C(═O)—, —O—, —S—, S(═O)—, —S(═O)₂—, —NR—, or a combination thereof, wherein, R and R′ are, each independently, hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, a substituted or unsubstituted C2 to C30 heterocyclic group, a substituted or unsubstituted C1 to C30 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, or a substituted or unsubstituted C2 to C30 heterocyclic group), a nitro group, a halogen atom, or a combination thereof, wherein n3 is an integer of 1 to 5, and
X₂ to X₉ are, each independently, —CR″— or N, wherein, R″ is hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, a substituted or unsubstituted C2 to C30 heterocyclic group, a substituted or unsubstituted C1 to C30 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, or a substituted or unsubstituted C2 to C30 heterocyclic group), a nitro group, a halogen atom, or a combination thereof.

In Chemical Formula 1, R₁ and R₂ may, each independently, be a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, a substituted or unsubstituted C2 to C20 heterocyclic group, a substituted or unsubstituted C1 to C20 alkoxy group, a substituted or unsubstituted amino group, a substituted or unsubstituted silyl group, a cyano group, a carboxyl group, —C(═O)R^{a}(wherein, R^{a} is hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, or a substituted or unsubstituted C2 to C20 heterocyclic group), a nitro group, a halogen atom, or a combination thereof.

In Chemical Formula 1, R₃ and R₄ may, each independently, be hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, a substituted or unsubstituted C2 to C20 heterocyclic group, a substituted or unsubstituted C1 to C20 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, or a substituted or unsubstituted C2 to C20 heterocyclic group), a nitro group, a halogen atom, or a combination thereof, or optionally, the groups of R₃ and R₄ may be linked to each other to form an aromatic or heteroaromatic ring.

In Chemical Formula 1, X₁ may be single bond, —(CRR′)ₙ₃—, —C(R)═C(R′)—, —C≡C—, —C(═O)—, —O—, —S—, S(═O)—, —S(═O)₂—, —NR—, or a combination thereof, wherein, R and R′ may, each independently, be hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, a substituted or unsubstituted C2 to C20 heterocyclic group, a substituted or unsubstituted C1 to C20 alkoxy group, a substituted or unsubstituted amino group, a substituted or unsubstituted silyl group, a cyano group, a carboxyl group, —C(═O)R^{a}(wherein, R^{a} is hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, or a substituted or unsubstituted C2 to C20 heterocyclic group), a nitro group, a halogen atom, or a combination thereof, wherein n3 is an integer of 1 to 3.

In Chemical Formula 1, X₂ to X₉ may, each independently, be —CR″— or N, wherein, R″ may be hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, a substituted or unsubstituted C2 to C20 heterocyclic group, a substituted or unsubstituted C1 to C20 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, or a substituted or unsubstituted C2 to C20 heterocyclic group), a nitro group, a halogen atom, or a combination thereof.

In Chemical Formula 1, X₁ may be single bond, and X₂ to X₉ may, each independently, be —CR″— or N, wherein, R″ may be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a}(wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof.

In Chemical Formula 1, X₁ may be single bond, and one of X₂ to X₉ may be N, and the others of X₂ to X₉ may, each independently, be —CR″, wherein, R″ may be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof.

In Chemical Formula 1,
X₁ may be —(CRR′)ₙ₃—, —C(═O)—, —O—, —S—, S(═O)—, —S(═O)₂—, —NR—, or a combination thereof, wherein, R and R′ may, each independently, be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof, wherein n3 is an integer of 1 or 2, and
X₂ to X₉ may, each independently, be —CR″— or N, wherein, R″ may be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof.

In Chemical Formula 1, X₂ to X₉ may, each independently, be —CR″—, wherein, R″ may be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof.

In Chemical Formula 1,
R₁ and R₂ may, each independently, be a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C1 to C10 alkoxy group, a substituted or unsubstituted amino group, a substituted or unsubstituted silyl group, a cyano group, a carboxyl group, —C(═O)R^{a}(wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof,
n1 and n2 may, each independently, be an integer of 1 to 3,
R₃ and R₄ may, each independently, be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a}(wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof, or optionally, the groups of R₃ and R₄ may be linked to each other to form an aromatic or heteroaromatic ring,
X₁ may be single bond, —(CRR′)ₙ₃—, —C(R)═C(R′)—, —C≡C—, —C(═O)—, —O—, —S—, S(═O)—, —S(═O)₂—, —NR—, or a combination thereof, wherein, R and R′ may, each independently, be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof, wherein n3 is an integer of 1 to 3, and
X₂ to X₉ may, each independently, be —CR″— or N, wherein, R″ may be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof.

In Chemical Formula 1,
R₁ and R₂ may, each independently, be a substituted or unsubstituted C1 to C10 saturated or unsaturated aliphatic hydrocarbon group, a substituted or unsubstituted C3 to C10 saturated or unsaturated alicyclic hydrocarbon group, or a combination thereof,
n1 and n2 may, each independently, be an integer of 2,
R₃ and R₄ may, each independently, be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a cyano group, a carboxyl group, a substituted or unsubstituted C1 to C10 alkanoyl group, an aldehyde group, or a combination thereof, or optionally, the groups of R₃ and R₄ may be linked to each other to form an aromatic or heteroaromatic ring,
X₁ may be single bond, —(CRR′)ₙ₃—, —C(═O)—, —O—, —S—, S(═O)—, —S(═O)₂—, —NR—, or a combination thereof, wherein, R and R′ may, each independently, be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, a substituted or unsubstituted C1 to C10 alkanoyl group, an aldehyde group, a nitro group, a halogen atom, or a combination thereof, wherein n3 is an integer of 1 to 3, provided that,
if X₁ is single bond, then, (i) one of X₂ to X₉ is N, and the others of X₂ to X₉ are, each independently, —CR″, or (ii) X₂ to X₉ are, each independently, —CR″, and
if X₁ is —C(═O)—, then, X₂ to X₉ are, each independently, —CR″,
wherein, R″ may be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a cyano group, a carboxyl group, a substituted or unsubstituted C1 to C10 alkanoyl group, an aldehyde group, a nitro group, a halogen atom, or a combination thereof.

In Chemical Formula 1,
R₁ and R₂ may, each independently, be a unsubstituted C1 to C10 alkyl group,
n1 and n2 may, each independently, be an integer of 2,
R₃ and R₄ may, each independently, be hydrogen, deuterium, a substituted or unsubstituted C1 to C10 alkyl group, a substituted or unsubstituted C6 to C10 aryl group, a substituted or unsubstituted C2 to C12 heterocyclic group, a substituted or unsubstituted amino group, a cyano group, or a combination thereof, or optionally, the groups of R₃ and R₄ may be linked to each other to form an aromatic or heteroaromatic ring,
X₁ may be single bond, —(CRR′)ₙ₃—, —C(═O)—, —O—, —S—, S(═O)—, —S(═O)₂—, —NR—, or a combination thereof, wherein, R and R′ may, each independently, be hydrogen, deuterium, a substituted or unsubstituted C1 to C10 alkyl group, a substituted or unsubstituted C3 to C10 cycloalkyl group, a substituted or unsubstituted C6 to C10 aryl group, a substituted or unsubstituted C1 to C10 alkoxy group, a substituted or unsubstituted amino group, a cyano group, a halogen atom, or a combination thereof, wherein n3 is an integer of 1 or 2, provided that,
if X₁ is single bond, then, (i) one of X₂ to X₉ is N, and the others of X₂ to X₉ are, each independently, —CR″, or (ii) X₂ to X₉ are, each independently, —CR″, and
if X₁ is —(CRR′)ₙ₃—, —C(═O)—, —O—, —S—, S(═O)—, —S(═O)₂—, or —NR—, then, X₂ to X₉ are, each independently, —CR″,
wherein, R″ may be hydrogen, deuterium, a substituted or unsubstituted C1 to C10 alkyl group, a substituted or unsubstituted C3 to C10 cycloalkyl group, a substituted or unsubstituted C6 to C10 aryl group, a substituted or unsubstituted C2 to C12 heterocyclic group, a cyano group, or a combination thereof.

Chemical Formula 1 may represented by Chemical Formula 2 or Chemical Formula 3:

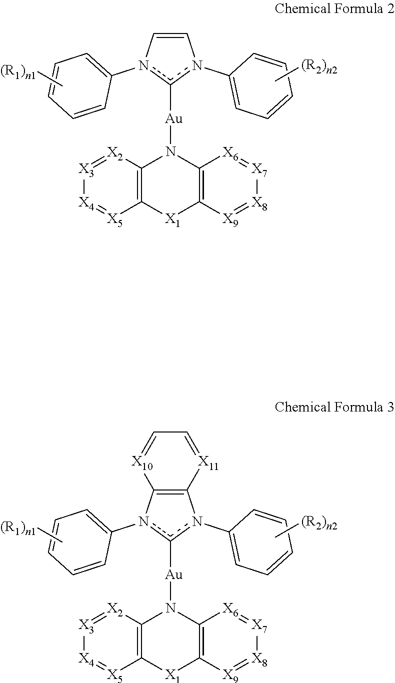

wherein in Chemical Formula 2 and Chemical Formula 3,
R₁ and R₂, n1 and n2, and X₁ to X₉ are the same as defined in Chemical Formula 1, and
wherein in Chemical Formula 3,
X₁₀ and X₁₁ are, each independently, be —CR′″— or N, wherein, R′″ may be hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, a substituted or unsubstituted C2 to C30 heterocyclic group, a substituted or unsubstituted C1 to C30 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, or a substituted or unsubstituted C2 to C30 heterocyclic group), a nitro group, a halogen atom, a combination thereof.

The compound represented by Chemical Formula 1 may include a compound represented in Group 1:

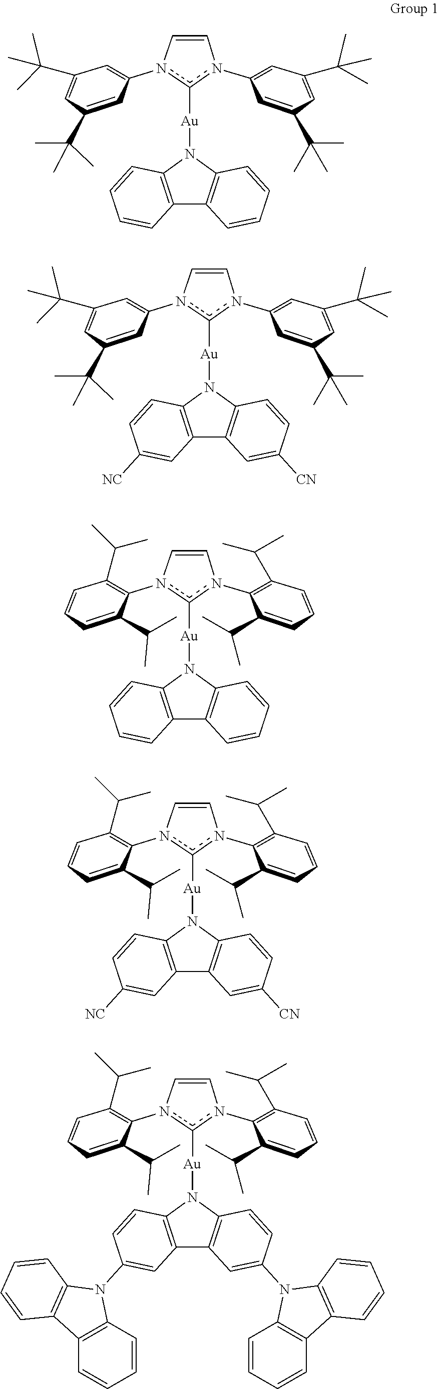

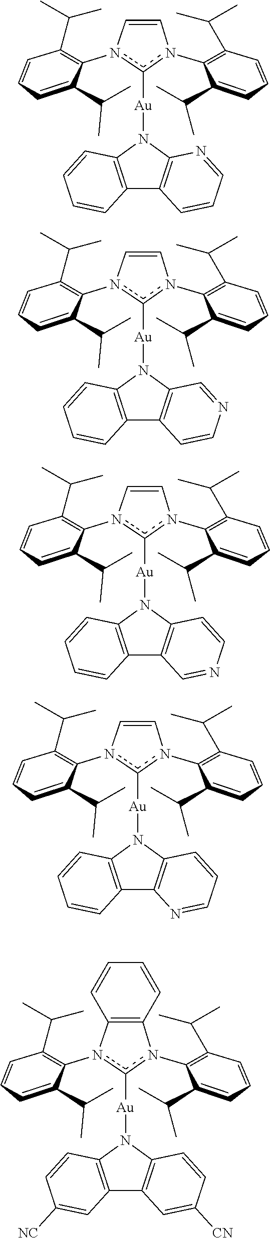

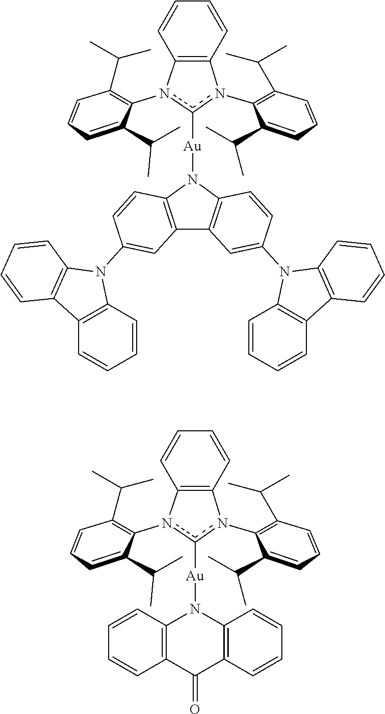

An organic electronic component according to another embodiment includes the compound according to an embodiment.

The organic electronic component may include an organic light-emitting diode (OLED) or a light-emitting electrochemical cell (LEEC).

The organic electronic component may include an anode and a cathode facing each other, and a light-emitting layer disposed between the anode and the cathode, and the compound may be included in the light-emitting layer.

The organic electronic component may further include a charge auxiliary layer between the anode and the light-emitting layer, and/or between the cathode and the light-emitting layer.

A light-emitting layer according to another embodiment may include the compound according to an embodiment.

An organic light-emitting diode (OLED) according to another embodiment may include the light-emitting layer.

A device according to another embodiment may include the OLED.

The compound according to an embodiment includes two ligands, i.e., a carbene ligand and an amido ligand, coordinated to Au(I), and may emit light based on TADF or phosphorescence at various wavelengths ranges depending on structures of the ligands and/or types of substituent bonded to the ligands. Accordingly, the compound may be included as a light-emitter in a light-emitting layer of various light-emitting devices, for example, an organic light-emitting diode. The light-emitting layer may be advantageously applied to various devices that require light emission in various wavelength ranges.

### BRIEF DESCRIPTION OF THE DRAWINGS

FIG. 1 shows a schematic diagram of an organic light emitting diode (OLED) according to an exemplary embodiment.

FIG. 2 shows the single crystal structure of [Au(^{Dtbp}Im)(CNCz)], the Au(I) complex synthesized in Example 12.

FIG. 3 is a steady-state UV-Vis absorption spectrum of [Au(^{Dipp}PZI)(ACD)] the Au(I) complex according to Example 1.

FIG. 4 is a steady-state UV-Vis absorption spectrum of [Au(^{Dipp}BZI)(CNCz)] the Au(I) complex according to Example 2.

FIG. 5 is s a steady-state UV-Vis absorption spectrum of [Au(^{Dipp}BZI)(Cz3)] the Au(I) complex according to Example 3.

FIG. 6 is s a steady-state UV-Vis absorption spectrum of [Au(^{Dipp}Im)(Cz)] the Au(I) complex according to Example 4.

FIG. 7 is a steady-state UV-Vis absorption spectrum of [Au(^{Dipp}Im)(CNCz)] Au(I) complex according to Example 5.

FIG. 8 is a steady-state UV-Vis absorption spectrum of [Au(^{Dipp}Im)(Cz3)] the Au(I) complex according to Example 6.

FIG. 9 is a steady-state UV-Vis absorption spectrum of [Au(^{Dipp}Im)(αCb)] the Au(I) complex according to Example 7.

FIG. 10 is a steady-state UV-Vis absorption spectrum of [Au(^{Dipp}Im)βCb)] the Au(I) complex according to Example 8.

FIG. 11 is a steady-state UV-Vis absorption spectrum of [Au(^{Dipp}Im)(γCb)] the Au(I) complex according to Example 9.

FIG. 12 is s a steady-state UV-Vis absorption spectrum of [Au(^{Dipp}Im)(δCb)] the Au(I) complex according to Example 10.

FIG. 13 is a steady-state UV-Vis absorption spectrum of [Au(^{Dtbp}Im)(Cz)] the Au(I) complex according to Example 11.

FIG. 14 is a steady-state UV-Vis absorption spectrum of [Au(^{Dtbp}Im)(CNCz)] the Au(I) complex according to Example 12.

FIG. 15 is a steady-state photoluminescence spectrum of [Au(^{Dipp}PZI)(ACD)] the Au(I) complex according to Example 1.

FIG. 16 is a steady-state photoluminescence spectrum of [Au(^{Dipp}BZI)(CNCz)] the Au(I) complex according to Example 2.

FIG. 17 is a steady-state photoluminescence spectrum of [Au(^{Dipp}BZI)(Cz3)] the Au(I) complex according to Example 3.

FIG. 18 is a steady-state photoluminescence spectrum of [Au(^{Dipp}Im)(Cz)] the Au(I) complex according to Example 4.

FIG. 19 is a steady-state photoluminescence spectrum of [Au(^{Dipp}Im)(CNCz)] Au(I) complex according to Example 5.

FIG. 20 is a steady-state photoluminescence spectrum of [Au(^{Dipp}Im)(Cz3)] the Au(I) complex according to Example 6.

FIG. 21 is a steady-state photoluminescence spectrum of [Au(^{Dipp}Im)(αCb)] the Au(I) complex according to Example 7.

FIG. 22 is a steady-state photoluminescence spectrum of [Au(^{Dipp}Im)βCb)] the Au(I) complex according to Example 8.

FIG. 23 is a steady-state photoluminescence spectrum of [Au(^{Dipp}Im)(γCb)] the Au(I) complex according to Example 9.

FIG. 24 is a steady-state photoluminescence spectrum of [Au(^{Dipp}Im)(δCb)] the Au(I) complex according to Example 10.

FIG. 25 is a steady-state photoluminescence spectrum of [Au(^{Dtbp}Im)(Cz)] the Au(I) complex according to Example 11.

FIG. 26 is a steady-state photoluminescence spectrum of [Au(^{Dtbp}Im)(CNCz)] the Au(I) complex according to Example 12.

FIG. 27 shows transient photoluminescence of [Au(^{Dipp}PZI)(ACD)] the Au(I) complex according to Example 1.

FIG. 28 shows transient photoluminescence of [Au(^{Dipp}BZI)(CNCz)] the Au(I) complex according to Example 2.

FIG. 29 shows transient photoluminescence of [Au(^{Dipp}BZI)(Cz3)] the Au(I) complex according to Example 3.

FIG. 30 shows transient photoluminescence of [Au(^{Dipp}Im)(Cz)] the Au(I) complex according to Example 4.

FIG. 31 shows transient photoluminescence of [Au(^{Dipp}Im)(CNCz)] Au(I) complex according to Example 5.

FIG. 32 shows transient photoluminescence of [Au(^{Dipp}Im)(Cz3)] the Au(I) complex according to Example 6.

FIG. 33 shows transient photoluminescence of [Au(^{Dipp}Im)(αCb)] the Au(I) complex according to Example 7.

FIG. 34 shows transient photoluminescence of [Au(^{Dipp}Im)βCb)] the Au(I) complex according to Example 8.

FIG. 35 shows transient photoluminescence of [Au(^{Dipp}Im)(γCb)] the Au(I) complex according to Example 9.

FIG. 36 shows transient photoluminescence of [Au(^{Dipp}Im)(δCb)] the Au(I) complex according to Example 10.

FIG. 37 shows transient photoluminescence of [Au(^{Dtbp}Im)(Cz)] the Au(I) complex according to Example 11.

FIG. 38 shows transient photoluminescence of [Au(^{Dtbp}Im)(CNCz)] the Au(I) complex according to Example 12.

FIG. 39 is a graph showing normalized electroluminescence intensity versus wavelength of an OLED including [Au(^{Dipp}PZI)(ACD)] according to Example 1 in the light emitting layer.

FIG. 40 is a graph showing current density versus voltage of an OLED including [Au(^{Dipp}PZI)(ACD)] according to Example 1 in the light emitting layer.

FIG. 41 shows a graph showing luminance versus current density of an OLED including [Au(^{Dipp}PZI)(ACD)] according to Example 1 in the light emitting layer.

FIG. 42 shows a graph showing external quantum efficiency versus current density of an OLED including [Au(^{Dipp}PZI)(ACD)] according to Example 1 in the light emitting layer.

FIG. 43 is a graph showing current efficiency versus current density of an OLED including [Au(^{Dipp}PZI)(ACD)] according to Example 1 in the light emitting layer.

FIG. 44 is a graph showing power efficiency versus current density of an OLED including [Au(^{Dipp}PZI)(ACD)] according to Example 1 in the light emitting layer.

### DETAILED DESCRIPTION

Hereinafter, exemplary embodiments will be described in detail so that a person skilled in the art would understand the same. The exemplary embodiments will be described more fully hereinafter with reference to the accompanying drawings, in which various embodiments are shown. This invention may, however, be embodied in many different forms, and should not be construed as limited to the embodiments set forth herein. The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

Herein, it should be understood that terms such as “comprises,” “includes,” or “have” are intended to designate the presence of an embodied feature, number, step, element, or a combination thereof, but does not preclude the possibility of the presence or addition of one or more other features, number, step, element, or a combination thereof.

In the drawings, the thickness of layers, films, panels, regions, etc., are exaggerated for clarity and like reference numerals designate like elements throughout the specification. It will be understood that when an element such as a layer, film, region, or substrate is referred to as being “on” or “above” another element, it may be directly on the other element or intervening elements may also be present. In contrast, when an element is referred to as being “directly on” another element, there are no intervening elements present.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In addition, “layer” herein includes not only a shape formed on the whole surface when viewed from a plan view, but also a shape formed on a partial surface.

The use of the term “the” and similar referential terms may refer to both the singular and the plural. Unless the order of the steps constituting the method is clearly stated or stated to the contrary, these steps may be performed in any appropriate order and are not necessarily limited to the order described.

The connections or connection members of lines between components shown in the drawings exemplify functional connections and/or physical or circuit connections, and in an actual device, they may be represented by a variety of alternative or additional functional, physical, or circuit connections.

As used herein, “at least one of A, B, or C,” “one of A, B, C, or any combination thereof” and “one of A, B, C, and any combination thereof” refer to each constituent element, and any combination thereof (e.g., A; B; C; A and B; A and C; B and C; or A, B, and C).

Herein, “a combination thereof” means a mixture of components, a stack, a composite, an alloy, a blend, and the like.

Hereinafter, unless otherwise defined, “substantially” or “approximately” or “about” means not only the stated value, but also the mean within an acceptable range of deviations, considering the errors associated with the corresponding measurement and the measurement of the measured value. For example, “substantially” or “approximately” can mean within ±10%, ±5%, ±3%, or ±1% or within standard deviation of the stated value. In the present specification, “X and Y are, each independently” means that X and Y may be the same as or different from each other.

As used herein, when a specific definition is not otherwise provided, the term “substituted” refers to a group or compound substituted with at least one substituent including a deuterium, a halogen (F, Br, Cl, or I), a hydroxyl group, a nitro group, a cyano group, an amino group (NH₂, NH(R₁₀₀) or N(R₁₀₁)(R₁₀₂), wherein R₁₀₀, R₁₀₁, and R₁₀₂ are the same or different, and are each independently a C1 to C10 alkyl group, an amidino group, a hydrazine group, a hydrazone group, a carboxyl group, an ester group, an acyl group, an alkyl group, an alkenyl group, an alkynyl group, a cycloalkyl group, a cycloalkenyl group, a cycloalkynyl group, an aryl group, a heteroaryl group, a heterocyclic group, an alkoxy group, an aryloxy group, a sulfonyl group, a sulfinyl group, a phosphine group, a selenyl group, a silyl group, or a combination thereof, in place of at least one hydrogen of a functional group, or the substituents may be linked to each other to provide a ring.

As used herein, when a specific definition is not otherwise provided, the term “saturated or unsaturated aliphatic hydrocarbon group” refers to a C1 to C30 alkyl group, a C2 to C30 alkenyl group, a C2 to C30 alkynyl group, a C1 to C30 alkylene group, a C2 to C30 alkenylene group, or a C2 to C30 alkynylene group, for example, a C1 to C20 alkyl group, a C2 to C20 alkenyl group, a C2 to C20 alkynyl group, a C1 to C20 alkylene group, a C2 to C20 alkenylene group, or a C2 to C20 alkynylene group.

As used herein, when a specific definition is not otherwise provided, the term “saturated or unsaturated alicyclic hydrocarbon group” refers to a C3 to C30 cycloalkyl group, a C3 to C30 cycloalkenyl group, a C3 to C30 cycloalkynyl group, a C3 to C30 cycloalkylene group, a C3 to C30 cycloalkenylene group, or a C3 to C30 cycloalkynyl group, for example, a C3 to C20 cycloalkyl group, a C3 to C20 cycloalkenyl group, a C3 to C20 cycloalkynyl group, a C3 to C20 cycloalkylene group, a C3 to C20 cycloalkenylene group, or a C3 to C20 cycloalkynylene group.

As used herein, when a specific definition is not otherwise provided, the term “aromatic hydrocarbon group” refers to a C6 to C30 aryl group or a C6 to C30 arylene group, for example, a C6 to C20 aryl group or a C6 to C20 arylene group.

As used herein, when a specific definition is not otherwise provided, the term “heterocyclic group” refers to a C2 to C30 cycloalkyl group, C2 to C30 cycloalkylene group, C2 to C30 cycloalkenyl group, C2 to C30 cycloalkenylene group, C2 to C30 cycloalkynyl group, C2 to C30 cycloalkynylene group, C2 to C30 heteroaryl group, or C2 to C30 heteroaryl group, in which one or more heteroatoms selected from the group consisting of O, S, N, P, Si, Se, or a combination thereof are contained as an element that forms the ring. For example, a C2 to C20 cycloalkyl group, a C2 to C20 cycloalkylene group, a C2 to C20 cycloalkenyl group, a C2 to C20 cycloalkenylene group, a C2 to C20 cycloalkynyl group, a C2 to C20 cycloalkynylene group, a C2 to C20 heteroaryl group, or a C2 to C20 heteroarylene group, in which 1 to 3 heteroatoms selected from the group consisting of O, S, N, P, Si, Se, or a combination thereof are contained as an element that forms the ring.

As used herein, the alicyclic hydrocarbon group, the aromatic hydrocarbon group, or the heterocyclic group may each consist of one ring, or comprise two or more rings, in which the two or more rings may be fused with each other, or linked by a linking group, such as, for example, single bond, alkylene group, arylene group, cycloalkylene group, —O—, —S—, —C(═O)— —C(═O)NH—, —C(═O)O—, —SO—, —(SO₂)—, and the like.

As used herein, when a specific definition is not otherwise provided, indicates a position where an atom or a group links to another atom or group.

The compound according to an embodiment may be represented by Chemical Formula 1:

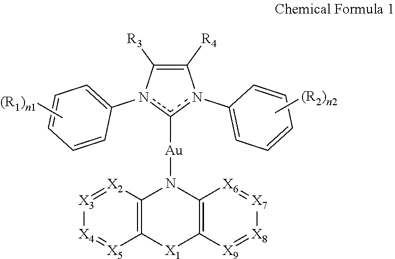

wherein in Chemical Formula 1,
R₁ and R₂ are, each independently, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, a substituted or unsubstituted C2 to C30 heterocyclic group, a substituted or unsubstituted C1 to C30 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, or a substituted or unsubstituted C2 to C30 heterocyclic group), a nitro group, a halogen atom, or a combination thereof,
n1 and n2 are, each independently, an integer of 0 to 5,
R₃ and R₄ are, each independently, hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, a substituted or unsubstituted C2 to C30 heterocyclic group, a substituted or unsubstituted C1 to C30 alkoxy group, a substituted or unsubstituted amino group, a substituted or unsubstituted silyl group, a cyano group, a carboxyl group, —C(═O)R^{a}(wherein, R^{a} is hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, or a substituted or unsubstituted C2 to C30 heterocyclic group), a nitro group, a halogen atom, a combination thereof, or optionally, the groups of R₃ and R₄ are linked to each other to form a ring,
X₁ is single bond, —(CRR′)ₙ₃—, —C(R)═C(R′)—, —C≡C—, —C(═O)—, —O—, —S—, S(═O)—, —S(═O)₂—, —NR—, or a combination thereof, wherein, R and R′ are, each independently, hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, a substituted or unsubstituted C2 to C30 heterocyclic group, a substituted or unsubstituted C1 to C30 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, or a substituted or unsubstituted C2 to C30 heterocyclic group), a nitro group, a halogen atom, or a combination thereof, wherein n3 is an integer of 1 to 5, and
X₂ to X₉ are, each independently, —CR″— or N, wherein, R″ is hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, a substituted or unsubstituted C2 to C30 heterocyclic group, a substituted or unsubstituted C1 to C30 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, or a substituted or unsubstituted C2 to C30 heterocyclic group), a nitro group, a halogen atom, or a combination thereof.

The compound represented by Chemical Formula 1 is a two-coordinated gold (Au(I)) complex including a ligand containing a carbene moiety (hereinafter, abbreviated as ‘carbene ligand’) and a ligand containing an amido moiety (hereinafter abbreviated as ‘amido ligand’), each of which is coordinated to the central metal, gold (Au(I)). The compound, as demonstrated through the examples described below, may exhibit thermally activated delayed fluorescence (TADF) or phosphorescence at various wavelengths depending on the structures of the carbene ligand and/or amido ligand, and/or substituent bonded to the ligands. It can display fluorescence (TADF). Therefore, the compound represented by Chemical Formula 1 can be advantageously applied to a light-emitting layer of an organic light-emitting diode (OLED).

In Chemical Formula 1, R₁ and R₂ may, each independently, be a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, a substituted or unsubstituted C2 to C20 heterocyclic group, a substituted or unsubstituted C1 to C20 alkoxy group, a substituted or unsubstituted amino group, a substituted or unsubstituted silyl group, a cyano group, a carboxyl group, —C(═O)R^{a}(wherein, R^{a} is hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, or a substituted or unsubstituted C2 to C20 heterocyclic group), a nitro group, a halogen atom, or a combination thereof. For example, R₁ and R₂ may, each independently, be a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof. For example, R₁ and R₂ may, each independently, be a substituted or unsubstituted C1 to C10 saturated or unsaturated aliphatic hydrocarbon group, a substituted or unsubstituted C3 to C10 saturated or unsaturated alicyclic hydrocarbon group, or a combination thereof, and are not limited thereto.

R₁ and R₂ are substituents that are each substituted to the two phenyl groups each bonded to the two nitrogen atoms of the carbene ring of Chemical Formula 1, and one or more of the various substituents described above may each independently be substituted on each phenyl group in a number of from 0 to 5. These substituents may respectively be substituted on the phenyl group to serve as an electron donor or electron acceptor, or to provide a steric effect to the compound.

For example, R₁ and R₂ may each independently be substituted to each phenyl group in a number of from 1 to 5, for example, from 1 to 4, from 1 to 3, for example, 1 or 2, or for example 1, but they may not be substituted at all. Here, “each independently” means that R₁ and R₂ may be the same as or different from each other, and/or that when two or more R₁ and/or R₂ exist, two or more R₁ may be the same as or different from each other, and also means that 2 or more R₂ may be the same as or different from each other. In addition, the number of R₁ and R₂ substituted to each phenyl group may also be the same as or different from each other.

In an example, R₁ and R₂ may be the same as each other, and the number of R₁ and R₂ substituted to each phenyl group may also be the same as each other.

In an example, R₁ and R₂ may be different from each other, and the number of R₁ and R₂ substituted to each phenyl group may be the same as or different from each other.

In an example, two or more R₁ are the same as each other, and two or more R₂ may be the same as each other, and the number of R₁ and R₂ substituted to each phenyl group may be the same as or different from each other.

In an example, two or more R₁ and two or more R₂ may all be the same, and may be substituted at the same position of each phenyl group corresponding to each other.

In an example, two or more R₁ and two or more R₂ may be different from each other, and each of R₁ and R₂ may be substituted at different position of each phenyl group.

In an example, R₁ and R₂ may each be present in a number of 2 or 3, and the 2 or 3 R₁ and R₂ may be substituted at the same position of each phenyl group corresponding to each other.

In an example, two R₁ and two R₂ may be present, and the two R₁ and two R₂ may be substituted at ortho positions with respect to the carbon atom of each phenyl group linked to the nitrogen atom of the carbene ring.

In an example, two R₁ and two R₂ may be present, and the two R₁ and two R₂ may be substituted at meta positions with respect to the carbon atom of each phenyl group linked to the nitrogen atom of the carbene ring.

In an example, R₁ and R₂ may, each independently, be a substituted or unsubstituted C1 to C10 alkyl group, for example, a substituted or unsubstituted C3 to C10 alkyl group, a substituted or unsubstituted C3 to C8 alkyl group, or a substituted or unsubstituted C3 to C5 alkyl group. The substituted or unsubstituted alkyl group is not particularly limited and may be linear, or branched. For example, the alkyl group may include methyl group, ethyl group, n-propyl group, isopropyl group, n-butyl group, isobutyl group, sec-butyl group, tert-butyl group, n-pentyl group, isopentyl group, tert-pentyl group, neopentyl group, 1,2-dimethyl propyl group, n-hexyl group, isohexyl group, 1,3-dimethylbutyl group, 1-isopropyl propyl group, 1,2-dimethylbutyl group, n-heptyl group, 1,4-dimethyl pentyl group, 3-ethyl pentyl group, 2-methyl-1-isopropyl propyl group, 1-ethyl-3-methyl butyl group, n-octyl group, 2-ethylhexyl group, 3-methyl-1-isopropyl butyl group, 2-methyl-1-isopropyl group, 1-tert-butyl-2-methyl propyl group, n-nonyl group, 3,5,5-trimethylhexyl group, n-decyl group, isodecyl group, n-undecyl group, 1-methyldecyl group, n-dodecyl group, n-tridecyl group, n-tetradecyl group, n-pentadecyl group, n-hexadecyl group, n-heptadecyl group, n-octadecyl group, and the like, and is not limited thereto.

In an example, R₁ and R₂ may, each independently, be isopropyl group, sec-butyl group, tert-butyl group, or a combination thereof, for example, be isopropyl group, tert-butyl group, or a combination thereof, or for example, both R₁ and R₂ may be isopropyl group, or both R₁ and R₂ may be tert-butyl group. In an example, two R₁ and two R₂ may be present, and the two R₁ and two R₂ may be present at the ortho position with respect to the carbon atom of each phenyl group linked to the nitrogen atom of the carbene ring. In another example, two R₁ and two R₂ may be present, and the two R₁ and two R₂ may be substituted at meta positions with respect to the carbon atom of each phenyl group linked to the nitrogen atom of the carbene ring.

In Chemical Formula 1, R₃ and R₄ may, each independently, be hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, a substituted or unsubstituted C2 to C20 heterocyclic group, a substituted or unsubstituted C1 to C20 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, or a substituted or unsubstituted C2 to C20 heterocyclic group), a nitro group, a halogen atom, a combination thereof, or optionally, the groups of R₃ and R₄ may be linked to each other to form ring, such as, for example, an aromatic or heteroaromatic ring. For example, R₃ and R₄ may, each independently, be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a}(wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, a combination thereof, or optionally, the groups of R₃ and R₄ may be linked to each other to form an aromatic or heteroaromatic ring. For example, R₃ and R₄ may, each independently, be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a cyano group, a carboxyl group, a substituted or unsubstituted C1 to C10 alkanoyl group, an aldehyde group, a combination thereof, or optionally, the groups of R₃ and R₄ may be linked to each other to form an aromatic or heteroaromatic ring.

R₃ and R₄ may, each independently, be hydrogen, or a substituent replacing hydrogen linked to the carbon atom in the carbene ring of Chemical Formula 1. In addition, R₃ and R₄ may be linked to each other to form a fused ring with the carbene ring. The substituents or the fused ring formed by the substituents may donate electrons to the carbene ring such that the carbene ring can better coordinate the gold (Au(I)) atom, or may donate electrons to or accept electrons from the carbene ring to adjust electron density by forming resonance with the carbene ring.

As R₁ and R₂, R₃ and R₄ may also be the same as or different from each other. For example, both R₃ and R₄ may be hydrogens, one of R₃ and R₄ may be hydrogen and the other may be a substituent that is not hydrogen, or both R₃ and R₄ may be substituents that are not hydrogens. When both R₃ and R₄ are not hydrogens, i.e., when at least one of R₃ and R₄ is not hydrogen, R₃ and R₄ may be linked to each other to form an aromatic or heteroaromatic ring. For example, the ring formed by linking R₃ and R₄ may be an aromatic ring, and for example, the aromatic ring may form a benzimidazole ring together with the carbene ring, but is not limited thereto. Alternatively, the ring formed by linking R₃ and R₄ may be a heteroaromatic ring, and for example, the heteroaromatic ring may include one or more nitrogen atoms in the ring, for example, two nitrogen atoms in the heteroaromatic ring. In this case, the heteroaromatic ring may form ‘pyrazinoimidazole’ together with the carbene ring, but is not limited thereto.

In an example, both R₃ and R₄ may be hydrogens, and in this case, the carbene ring includes only the two phenyl groups substituted to the two nitrogen atoms in the ring as substituents, and is in a single ring structure.

In an example, R₃ and R₄ may from an aromatic or heteroaromatic ring by linking to each other, and in this case, the aromatic or heteroaromatic ring may form a condensed ring with the carbene ring.

In an example, R₃ and R₄ may, each independently, be hydrogen, deuterium, a substituted or unsubstituted C1 to C10 alkyl group, a substituted or unsubstituted C6 to C10 aryl group, a substituted or unsubstituted C2 to C12 heterocyclic group, a substituted or unsubstituted amino group, a cyano group, a substituted or unsubstituted C1 to C10 alkanoyl group, an aldehyde group, or a combination thereof, or optionally, the groups of R₃ and R₄ may be linked to each other to form an aromatic or heteroaromatic ring.

In Chemical Formula 1, X₁ may be single bond, —(CRR′)ₙ₃—, —C(R)═C(R′)—, —C≡C—, —C(═O)—, —O—, —S—, S(═O)—, —S(═O)₂—, —NR—, or a combination thereof, wherein, R and R′ may, each independently, be hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, a substituted or unsubstituted C2 to C20 heterocyclic group, a substituted or unsubstituted C1 to C20 alkoxy group, a substituted or unsubstituted amino group, a substituted or unsubstituted silyl group, a cyano group, a carboxyl group, —C(═O)R^{a}(wherein, R^{a} is hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, or a substituted or unsubstituted C2 to C20 heterocyclic group), a nitro group, a halogen atom, or a combination thereof, wherein n3 is an integer of 1 to 3. For example, X₁ may be single bond, —(CRR′)ₙ₃—, —C(═O)—, —O—, —S—, S(═O)—, —S(═O)₂—, —NR—, or a combination thereof, wherein, R and R′ may, each independently, be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof, wherein n3 is an integer of 1 or 2.

In Chemical Formula 1, X₂ to X₉ may, each independently, be —CR″— or N, wherein, R″ may be hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, a substituted or unsubstituted C2 to C20 heterocyclic group, a substituted or unsubstituted C1 to C20 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, or a substituted or unsubstituted C2 to C20 heterocyclic group), a nitro group, a halogen atom, or a combination thereof. For example, X₂ to X₉ may, each independently, be —CR″— or N, wherein, R″ may be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a}(wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof, and for example, R″ may be hydrogen, deuterium, a substituted or unsubstituted C1 to C10 alkyl group, a substituted or unsubstituted C3 to C10 cycloalkyl group, a substituted or unsubstituted C6 to C10 aryl group, a substituted or unsubstituted C2 to C12 heterocyclic group, a cyano group, a substituted or unsubstituted C1 to C10 alkanoyl group, an aldehyde group, or a combination thereof, and is not limited thereto.

In an example, if X₁ is single bond, then X₂ to X₉ may, each independently, be —CR″— or N, wherein, R″ may be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof.

In an example, if X₁ is single bond, then one of X₂ to X₉ may be N, and the other of X₂ to X₉ may, each independently, be —CR″, wherein, R″ may be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof.

In Chemical Formula 1,
X₁ may be —(CRR′)ₙ₃—, —C(═O)—, —O—, —S—, S(═O)—, —S(═O)₂—, —NR—, or a combination thereof, wherein, R and R′ may, each independently, be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof, wherein n3 is an integer of 1 or 2, and
X₂ to X₉ may, each independently, be —CR″— or N, wherein, R″ may be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof, or for example, all of X₂ to X₉ may, each independently, be —CR″, wherein R″ may be the same as defined above.

In an example, X₁ may be single bond, —(CRR′)ₙ₃—, —C(R)═C(R′)—, —C≡C—, —C(═O)—, —O—, —S—, S(═O)—, —S(═O)₂—, —NR—, or a combination thereof, wherein, R and R′ may, each independently, be the same as defined above, and X₂ to X₉ may, each independently, be —CR″— or N, wherein, R″ may be the same as defined above.

In an example, X₁ may be single bond, —(CRR′)ₙ₃—, —C(═O)—, —O—, —S—, S(═O)—, —S(═O)₂—, —NR—, or a combination thereof, wherein, R and R′ may, each independently, be the same as defined above, provided that
if X₁ is single bond, then, (i) one of X₂ to X₉ is N, and the others of X₂ to X₉ are, each independently, —CR″, or (ii) X₂ to X₉ are, each independently, —CR″, and
if X₁ is —C(═O)—, then, X₂ to X₉ are, each independently, —CR″,
wherein, R″ may be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a cyano group, a carboxyl group, a substituted or unsubstituted C1 to C10 alkanoyl group, an aldehyde group, a nitro group, a halogen atom, or a combination thereof.

For example, in Chemical Formula 1, X₁ may be single bond, —(CRR′)ₙ₃—, —C(═O)—, —O—, —S—, S(═O)—, —S(═O)₂—, —NR—, or a combination thereof, wherein, R and R′ may, each independently, be hydrogen, deuterium, a substituted or unsubstituted C1 to C10 alkyl group, a substituted or unsubstituted C3 to C10 cycloalkyl group, a substituted or unsubstituted C6 to C10 aryl group, a substituted or unsubstituted C1 to C10 alkoxy group, a substituted or unsubstituted amino group, a cyano group, a halogen atom, or a combination thereof, wherein n3 is an integer of 1 or 2, provided that
if X₁ is single bond, then, (i) one of X₂ to X₉ is N, and the others of X₂ to X₉ are, each independently, —CR″, or (ii) X₂ to X₉ are, each independently, —CR″, and
if X₁ is —(CRR′)ₙ₃—, —C(═O)—, —O—, —S—, S(═O)—, —S(═O)₂—, or —NR—, then, X₂ to X₉ are, each independently, —CR″,
wherein, R″ may be hydrogen, deuterium, a substituted or unsubstituted C1 to C10 alkyl group, a substituted or unsubstituted C3 to C10 cycloalkyl group, a substituted or unsubstituted C6 to C10 aryl group, a substituted or unsubstituted C2 to C12 heterocyclic group, a cyano group, or a combination thereof.

In Chemical Formula 1, X₁, and X₂ to X₉ may form an amido ligand coordinated to Au(I) atom of the compound represented by Chemical Formula 1. Here, when X₁ is single bond, and X₂ to X₉ are, each independently, —CR″, the amido ligand may be a substituted or unsubstituted carbazole ligand. In an example, R″ of —CR″— may all be hydrogen, and in this case, the amido ligand may be an unsubstituted carbazole.

In an example, the amido ligand may or may not have a substituent at the position of X₄ and X₈. The substituent may donate or accept electrons to adjust electron density of the carbazole. For example, the substituent may be a cyano group, a carbazole group, or a combination thereof, but is not limited thereto.

In another example, when X₁ is single bond, one of X₂ to X₉ is N, and the others of X₂ to X₉ are, each independently, —CR″, and in this case, R″ of —CR″— may all be hydrogens. When one of X₂ to X₉ is N, any one of X₂ to X₉ may be N, and the position is not specifically limited.

Chemical Formula 1 may be represented by Chemical Formula 2 or Chemical Formula 3:

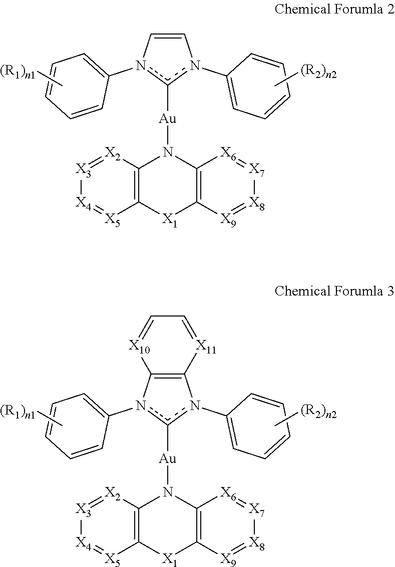

wherein in Chemical Formula 2 and Chemical Formula 3,
R₁ and R₂, n1 and n2, and X₁ to X₉ are defined the same as in Chemical Formula 1, and
wherein in Chemical Formula 3,
X₁₀ and X₁₁ are, each independently, be —CR′″— or N, wherein, R′″ may be hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, a substituted or unsubstituted C2 to C30 heterocyclic group, a substituted or unsubstituted C1 to C30 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, or a substituted or unsubstituted C2 to C20 heterocyclic group), a nitro group, a halogen atom, a combination thereof.

In an example, in Chemical Formula 2, R₁ and R₂ may, each independently, be a substituted or unsubstituted C1 to C10 saturated or unsaturated aliphatic hydrocarbon group, a substituted or unsubstituted C3 to C10 saturated or unsaturated alicyclic hydrocarbon group, or a combination thereof. For example, in Chemical Formula 2, R₁ and R₂ may, each independently, be a substituted or unsubstituted C1 to C10 saturated or unsaturated aliphatic hydrocarbon group, for example, a substituted or unsubstituted C1 to C10 alkyl group, for example, an isopropyl group, a tert-butyl group, or a combination thereof, and are not limited thereto.

In an example, in Chemical Formula 2, R₁ and R₂ may, each independently, be two isopropyl groups substituted at the ortho positions with respect to the carbon atom of each phenyl group linked to the nitrogen atoms of the carbene ring. In another example, in Chemical Formula 2, R₁ and R₂ may, each independently, be two tert-butyl groups substituted at the meta positions with respect to the carbon atom of each phenyl group linked to the nitrogen atoms of the carbene ring.

In an example, in Chemical Formula 2, X₁ may be single bond, and (i) one of X₂ to X₉ may be N, and the others of X₂ to X₉ may, each independently, be —CR″, or (ii) X₂ to X₉ may, each independently, be —CR″, wherein, R″ may be hydrogen, deuterium, a substituted or unsubstituted C1 to C10 alkyl group, a substituted or unsubstituted C6 to C10 aryl group, a substituted or unsubstituted C2 to C12 heterocyclic group, a substituted or unsubstituted C1 to C10 alkoxy group, a substituted or unsubstituted amino group, a cyano group, a carboxyl group, a nitro group, a halogen atom, or a combination thereof.

In another example, in Chemical Formula 2, X₁ may be single bond, and X₂ to X₉ may, each independently, be —CR″, wherein R″ may be hydrogen, deuterium, a substituted or unsubstituted C1 to C10 alkyl group, a substituted or unsubstituted C2 to C12 heterocyclic group, a substituted or unsubstituted C1 to C10 alkoxy group, a substituted or unsubstituted amino group, a cyano group, a halogen atom, or a combination thereof.

In an example, in Chemical Formula 2, X₁ may be single bond, one of X₂ to X₉ may be N, and the others of X₂ to X₉ may, each independently, be —CR″.

In an example, in Chemical Formula 3, both of X₁₀ and X₁₁ may be —CR′″, or may be N.

In an example, in Chemical Formula 3, if both of X₁₀ and X₁₁ are —CR′″, then, R′″ may be hydrogen, and in this case, R₁ and R₂ may, each independently, be two isopropyl groups substituted at the positions ortho, or two ter-butyl groups substituted at the positions meta with respect to the carbon atom of each phenyl groups that are linked to the nitrogen atoms of the carbene ring.

Further, in an example, in Chemical Formula 3, if both of X₁₀ and X₁₁ are —CR′″, and R′″ are all hydrogen, then, X₁ may be single bond, and X₂ to X₉ may, each independently, be —CR″, wherein R″ may be hydrogen, deuterium, a substituted or unsubstituted C1 to C10 alkyl group, a substituted or unsubstituted C2 to C12 heterocyclic group, a substituted or unsubstituted C1 to C10 alkoxy group, cyano group, a halogen atom, or a combination thereof. In an example, in Chemical Formula 3, if X₁ is single bond, and X₂ to X₉ are all —CR″, then R″ substituted at X₄ and X₈ may, each independently, be a substituted or unsubstituted C1 to C10 alkyl group, a substituted or unsubstituted C2 to C12 heterocyclic group, a substituted or unsubstituted C1 to C10 alkoxy group, a cyano group, a halogen atom, or a combination thereof, and the other R″ substituted to X₂, X₃, X₅, X₆, X₇, and X₉, may all be hydrogens, but is not limited thereto.

In an example, in Chemical Formula 3, if both of X₁₀ and X₁₁ are N, then, X₁ may be —C(═O)—, and X₂ to X₉ may, each independently, be —CR″, wherein R″ may be hydrogen, deuterium, a substituted or unsubstituted C1 to C10 alkyl group, a substituted or unsubstituted C2 to C12 heterocyclic group, a substituted or unsubstituted C1 to C10 alkoxy group, a cyano group, a halogen atom, or a combination thereof. In an example, in Chemical Formula 3, if X₁ is —C(═O)—, and single bond, and X₂ to X₉ are all —CR″, then R″ may all be hydrogens, but is not limited thereto.

The compound represented by Chemical Formula 1 may include a compound represented in Group 1:

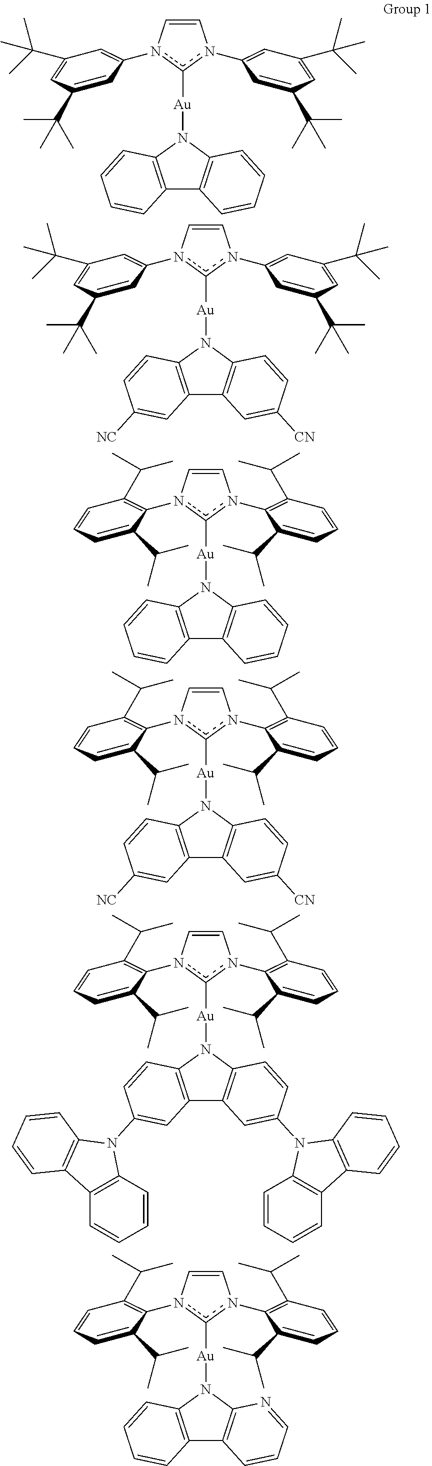

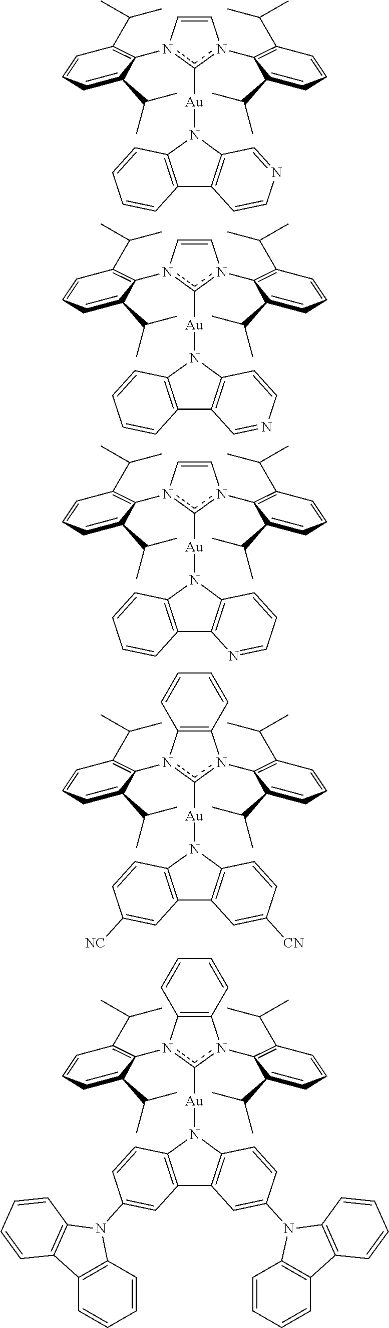

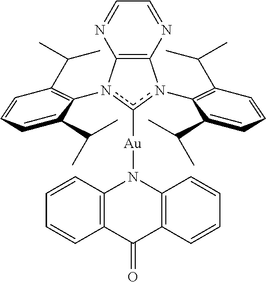

The compound according to an embodiment absorbs light in UV-Vis region, and emits light having a longer wavelength than absorbed. For example, the compound may absorb light having a wavelength of less than or equal to 600 nm, for example, less than or equal to 550 nm, less than or equal to 500 nm, or less than or equal to 450 nm, and may emit light having a photoluminescence peak wavelength in the range of about 400 nm to about 600 nm. The photoluminescence lifetime of the compound may be greater than about 0.3 microseconds (μs), for example, from about 0.3 μs to about 50 μs. From the examples described below, it can be seen that the peak photoluminescence wavelength and/or photoluminescence lifetime may be adjusted by changing the structure of the ligand of the compound and/or the substituent substituted for the ligand. Therefore, the compound according to an embodiment may be advantageously applied to various products that require luminescent properties in various wavelength ranges. The various products may include an organic electronic component containing a compound according to an embodiment, and the organic electronic component may include a compound according to an embodiment in a light-emitting layer.

The organic electronic component may be an organic light emitting diode (OLED) or a light-emitting electrochemical cell (LEEC).

OLED includes one or more organic layers disposed between and electrically connected to an anode and a cathode. When current is applied, the anode injects holes into the organic layer(s) and the cathode injects electrons. The injected holes and electrons each move toward oppositely charged electrodes. When an electron and a hole become localized on the same molecule, an “exciton” is created, which is a localized electron-hole pair with an excited energy state. When excitons relax through a photoemission mechanism, light is emitted. In some cases, excitons may localize onto the excimer or exciplex, and non-radiative mechanisms, such as thermal relaxation, may occur, but are generally considered undesirable.

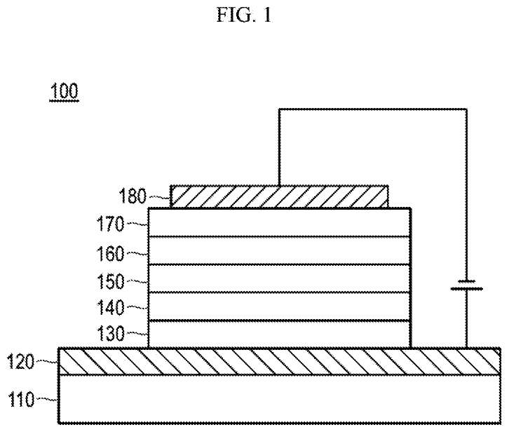

FIG. 1 is a diagram schematically showing an organic light emitting diode (OLED) 100 according to an embodiment. The drawings are not necessarily drawn to scale.

Referring to FIG. 1, OLED 100 according to an embodiment includes a substrate 110, anode 120, a hole transport layer 130 disposed on the anode 120, a hole injection layer 130 disposed between the anode 120 and the hole transport layer 140. As used herein, the term “disposed on” is inclusive of two layers in direct contact with no intervening layers, and two adjacent layers with one or more layers optionally present between the two adjacent layers. A person of ordinary skill would further recognize and understand that the presence of a hole injection layer 130 is optional, and thus, may be omitted from the device. The OLED 100 also includes a light emitting layer 150 disposed on the hole transport layer 140, an electron transport layer 160 disposed on the light emitting layer 150, an electron injection layer 170 disposed on the electron transport layer 160, and a cathode 180 disposed on the electron injection layer 170. OLED 100 may be fabricated by sequentially stacking the layers in the order as described.

As depicted in FIG. 1, anode 120 may be directly connected to a driving power source so that current flows through the light emitting layer 150. Anode 120 may be optically transparent, and thus, may be a transparent electrode through which light emitted from the light emitting layer 150 can transmit. Anode 120 may include a material having light transmittance in at least visible light wavelength region, but is not limited thereto. Anode 120 may further include a material having light transmittance in an infrared or ultraviolet (UV) wavelength region. For example, anode 120 may consist of an optically transparent material.

In an embodiment, anode 120 may include molybdenum oxide, tungsten oxide, vanadium oxide, rhenium oxide, niobium oxide, tantalum oxide, titanium oxide, zinc oxide, nickel oxide, copper oxide, cobalt oxide, manganese oxide, chromium oxide, indium oxide, tin oxide, or a combination thereof. However, the anode 120 according to an embodiment is not necessarily limited thereto but may include a material further having light transmittance with respect to light in an infrared or ultraviolet (UV) wavelength region. The anode 120 according to another embodiment may be a semi-transmittable material selectively transmitting light in a particular wavelength region as well as have the capability to reflect light in a visible light wavelength region back toward the anode 120 and out of the device.

Anode 120 may be disposed on a substrate 110 as shown in FIG. 1. The substrate 110 may be a transparent insulating substrate, e.g., a glass or metal oxide, or may be made of a ductile or flexible material such as a plastic. The substrate 110 may include glass or a polymer material in a film having a glass transition temperature (Tg) of greater than about 150° C. For example, the substrate may be a COC (cycloolefin copolymer) or COP (cycloolefin polymer) based material.

In an embodiment, the substrate 110 may support the hole injection layer 130, the hole transport layer 140, the light emitting layer 150, and the electron transport layer 160 disposed between the anode 120 and the cathode 180. Alternatively, a substrate may be disposed on the cathode 180, or may be omitted.

Cathode 180 may be directly connected to a driving power source so that current flows through the light emitting layer 150. In an embodiment, the cathode 180 may include at least one selected from silver (Ag), aluminum (AI), copper (Cu), gold (Au), and an alloy thereof, molybdenum oxide, tungsten oxide, vanadium oxide, rhenium oxide, niobium oxide, tantalum oxide, titanium oxide, zinc oxide, nickel oxide, copper oxide, cobalt oxide, manganese oxide, chromium oxide, indium oxide, tin oxide, or a combination thereof. However, the cathode 180 according to an embodiment is not necessarily limited thereto.

The cathode 180 may include a semi-transmittable material that selectively transmits light in a particular wavelength region and may also function to reflect light in a visible light wavelength region toward the anode 120. When the cathode 180 functions as a reflecting electrode, the anode 120 may be a light-transmitting electrode formed of a material transmitting light in at least visible light wavelength region or a semi-transmittable electrode selectively transmitting light in a particular wavelength region.

Anode 120 and cathode 180 may each be formed by depositing a material for forming an electrode on the substrate 110 or an organic layer by a method known in the art such as sputtering.

The OLED 100 according to an embodiment may have a conventional structure in which the substrate 110 and each constituent element are disposed in the aforementioned stacking order as shown in FIG. 1. However, the embodiment is not necessarily limited thereto, and may have various structures as long as it satisfies the stacking order between the constituent elements of the aforementioned OLED 100. For example, when the substrate 110 is disposed on the cathode 180 rather than adjacent to the anode 120, the device 100 may have an inverted structure.

The hole injection layer 130 may be disposed directly on the anode 120. The hole injection layer 130 may serve to supply holes to the light emitting layer 150 together with the hole transport layer 140. However, the hole injection layer 130 may be omitted in consideration of the thickness, material, and the like of the hole transport layer 140.

The hole injection layer 130 may be formed of a p-type semiconductor or a material doped with a p-type semiconductor. The hole injection layer 130 may include, for example, poly(3,4-ethylenedioxythiophene) (PEDOT) or a derivative thereof, poly(styrenesulfonate) (PSS] or a derivative thereof, poly-N-vinylcarbazole (PVK) or a derivative thereof, polyphenylene vinylene or a derivative thereof, poly p-phenylene vinylene (PPV) or a derivative thereof, polymethacrylate or a derivative thereof, poly(9,9-octylfluorene) or a derivative thereof, poly(spiro-bifluorene) or a derivative thereof, tris(4-carbazolyl-9-ylphenyl)amine (TCTA), N,N′-diphenyl-N,N′-bis(3-methylphenyl)-(1,1′-biphenyl)-4,4′-diamine (TPD), N,N′-di(naphthalen-1-yl)-N—N′-diphenyl-benzidine (NPB), tris(3-methylphenylphenylamino)-triphenylamine (m-MTDATA), poly-TPD, a metal oxide such as NiO or MoO3, or a combination thereof, but is not necessarily limited thereto.

The hole transport layer 140 may be disposed on the anode 120, for example on the anode 120 and the hole injection layer 130. The hole transport layer 140 serves to supply and transport holes to the light emitting layer 150. The hole transport layer 140 is formed adjacent to the light emitting layer 150, and may be in direct contact with the light emitting layer 150.

In an embodiment, the hole transport layer 140 may include a material having hole transport properties. Examples of the material having hole transport properties include a p-type semiconductor or a material doped with a p-type semiconductor. The material having hole transport properties are not limited to specific materials and may include a polymer, an oligomer, a metal oxide, or a combination thereof.

Examples of the material having hole transport properties may include a poly(3,4-ethylenedioxythiophene) derivative, a poly(styrenesulfonate) derivative, a poly-N-vinylcarbazole derivative, a polyphenylenevinylene derivative, a polyparaphenylenevinylene derivative, a polymethacrylate derivative, a polyarylamine derivative, a polyaniline derivative, a polypyrrole derivative, a poly(9,9-dioctylfluorene) derivative, a poly(spiro-bifluorene) derivative, tris(4-carbazolyl-9-ylphenyl)amine (TCTA), N,N′-diphenyl-N,N′-bis(3-methylphenyl)-(1,1′-biphenyl)-4,4′-diamine (TPD), N,N′-di(naphthalen-1-yl)-N—N′-diphenyl-benzidine (NPB), tris(3-methylphenylphenylamino)-triphenylamine (m-MTDATA), poly-TPD, NiO, MoO3, or a combination thereof, but are not necessarily limited thereto.

In an embodiment, a thickness of the hole transport layer 140 may be adjusted in consideration of a hole-electron balance with the hole injection layer 130, the hole transport layer 140, and/or the light emitting layer 150 in the device. The thickness of the hole transport layer 140 may be for example greater than or equal to about 10 nm, greater than or equal to about 15 nm, or greater than or equal to about 20 nm, and for example, less than or equal to about 80 nm, less than or equal to about 70 nm, less than or equal to about 60 nm, or less than or equal to about 50 nm, or for example about 10 nm to about 80 nm, about 10 nm to about 70 nm, about 10 nm to about 60 nm, about 10 mm to about 50 nm, about 10 nm to about 40 nm, or about 20 nm to about 40 nm.

For example, the hole transport layer 140 may be formed through a wet coating process such as spin-coating and the like. For example, the hole transport layer 140 and the light emitting layer 150, and in particular, both the hole transport layer 140 and the light emitting layer 150 may be formed by using the wet coating process. By using the wet coating process, the hole transport layer 140 and/or the light emitting layer 150 may be formed in a simple method.

The light emitting layer 150 may be disposed on the hole transport layer 140 and may include a compound according to one embodiment. The light-emitting layer 150 is a place where electrons and holes transferred by the current supplied from the anode 120 and the cathode 180 combine, and the electrons and holes meet and combine in the light-emitting layer 150 to generate excitons. The generated excitons may go through intersystem crossing (ISC) from the singlet (S1) energy state to the triplet (T1) energy state by the gold (Au(I)) complex compound according to an embodiment, or may go through reverse intersystem crossing (rISC) from the triplet (T1) energy state to the singlet (S1) energy state by thermal energy derived from room temperature. Therefore, the compound according to an embodiment may collect all the singlet and/or triplet excitons and emit phosphorescence and/or thermally activated delayed fluorescence (TADF) that may increase internal luminescence quantum efficiency. Accordingly, the light-emitting layer 150 can emit light having a specific wavelength by including a compound according to an embodiment.

In addition to the gold (Au(I)) complex compound according to an embodiment, the light-emitting layer 150 may further include a compound having electron transport or hole transport properties that assists transfer of electrons or holes, i.e., an electron-transporting host and/or a hole-transporting host. The electron-transporting host and/or the hole-transporting host may be any electron-transporting host and/or hole-transporting host that have been used in the light emitting layer, hole transport layer, electron transport layer, hole injection layer, electron injection layer, etc. of the conventional OLED, and there is no specific limit thereto. The electron-transporting host and/or the hole-transporting host may be selected from various compounds known in the art, and may be used as alone or in combination of two or more types.

In an embodiment, a thickness of the light emitting layer 150 may be, for example, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, greater than or equal to about 20 nm, greater than or equal to about 25 nm, greater than or equal to about 30 nm, or greater than or equal to about 35 nm. A thickness of the light emitting layer 150 may be less than or equal to about 100 nm, for example, less than or equal to about 90 nm, less than or equal to about 80 nm, less than or equal to about 70 nm, less than or equal to about 60 nm, less than or equal to about 50 nm, or less than or equal to about 40 nm. The thickness of the light emitting layer 150 may be about 10 nm to about 60 nm, for example about 15 nm to about 60 nm, about 20 nm to about 60 nm, about 25 nm to about 60 nm, or about 25 nm to about 50 nm.

In an embodiment, the electron transport layer 160 may be disposed on the light emitting layer 150. The electron transport layer 160 may have electron transfer characteristics and/or hole block characteristics, and may include, for example, a material having electron transfer characteristics and/or hole block characteristics, such as, for example, an n-type organic semiconductor.

Examples of n-type organic semiconductors may include n-type monomolecular organic semiconductors, n-type polymer organic semiconductors, or combination thereof.

Examples of the n-type monomolecular organic semiconductor may be 1,3,5-tri(diphenylphosphoryl-phen-3-yl) benzene (TP3PO), 1,3,5-triazine-2,4,6-triyl)tris(benzene-3,1-diyl)tris(diphenylphosphine oxide) (POT2T), diphenylbis(4-(pyridin-3-yl)phenyl)silane (DPPS), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 1,3,5-tris(1-phenyl-1Hbenzimidazole-2-yl)benzene (TPBi), 4,7-diphenyl-1,10-phenanthroline (Bphen), 1,3-bis[2-(2,2′-bipyridin-6-yl)-1,3,4-oxadiazol-5-yl]benzene (Bpy-OXD), 2-(4-biphenyl)-5-(4-tert-butylphenyl)-1,3,4-oxadiazole (PBD), bathocuproine (BCP), 4,4′-bis(carbazol-9-yl)-2,2′-dimethylbiphenyl (CDBP), tris[3-(3-pyridyl)-mesityl]borane (3TPYMB), or a combination thereof.

Examples of the n-type polymer organic semiconductors may include conjugation polymer compounds including elements such as phosphorus (P), oxygen (O), nitrogen (N), and the like, and may specifically include a quinolone-containing compound, a triazine-containing polymer compound, a quinoline-containing polymer compound, a triazole-containing compound, or a naphthalene-containing polymer compound.

In an embodiment, the electron transport layer 160 may be disposed between the light emitting layer 150 and the cathode 180, and specifically directly on the light emitting layer 150, and serves to transport electrons to the light emitting layer 150.

In an embodiment, a thickness of the electron transport layer 160 may be varied in consideration of an electron-hole balance with the hole injection layer 130, hole transport layer 140, and/or light emitting layer 150, in the device, and the thickness of the electron transport layer 160 may be, for example, greater than or equal to about 10 nm, greater than or equal to about 15 nm, or greater than or equal to about 20 nm and for example less than or equal to about 100 nm, less than or equal to about 90 nm, less than or equal to about 80 nm, less than or equal to about 70 nm, less than or equal to about 60 nm, less than or equal to about 50 nm, or less than or equal to about 40 nm, or for example about 10 nm to about 100 nm, about 10 nm to about 60 nm, about 10 nm to about 50 nm, about 10 mm to about 40 nm, or about 15 nm to about 40 nm.

Electron injection layer 170 may be formed between the electron transport layer 160 and the cathode 180 to facilitate injection of electrons, and in addition, although not shown in FIG. 1, a hole blocking layer to prevent the movement of holes may also be included.

A thickness of the electron injection layer 170 may be appropriately selected and may be about 1 nm or more and 500 nm or less, but is not limited thereto. The electron injection layer 170 may be an organic layer formed by deposition.

The electron injection layer 170 and/or the hole blocking layer may include, for example, 1,4,5,8-naphthalene-tetracarboxylic dianhydride (NTCDA), basocuproine (BCP), tris[3-(3-pyridyl)-mesityl]borane (3TPYMB), LiF, Alq₃, Gaq₃, Inq₃, Znq₂, Zn(BTZ)₂, BeBq₂, Liq, n-type metal oxides (e.g. ZnO, HfO₂, etc.), It may include at least one selected from Bphen, and combinations thereof, but is not limited thereto.

Although embodiments of the invention have been described in detail, this is for illustrative purposes only and is illustrative at the same time, and is not intended to limit the scope of the invention. It is clear that the scope of the invention should be construed in accordance with the appended claims.

### Example

The effects of the present invention will be explained using the following examples. However, the technical scope of the invention is not limited to the following examples.

### Materials, Measurements, and Instruments for Measurements

Commercially available chemicals, including 2,3-dichloropyrazine, 2,6-diisopropyl aniline, tris(dibenzylideneacetone)dipalladium(0) (Pd₂(dba)₃), tricyclohexylphosphine (PCy₃), trimethylsilyl chloride, sodium tert-butoxide (NaO^{t}Bu), chloro(dimethylsulfido)gold(I), potassium bis(trimethylsilyl)amide (KHMDS), triethylorthoformate, and [Au(^{Dipp}Im)(Cl)] were used as received, unless otherwise stated. Toluene and tetrahydrofuran (THF) were distilled over sodium prior to use. Au(I) complexes were prepared following the methods developed by Hame et al. after minor modifications (R. Hamze, M. Idris, D. S. M. Ravinson, M. C. Jung, R. Haiges, P I. Djurovich, M. E. Thompson, Front. Chem. 2020, 8, 401).

All glassware, magnetic stir bars, syringes, and needles were dried in a convection oven at 120° C. Reactions were monitored by using thin-layer chromatography (TLC). Commercial TLC plates (silica gel 254, Merck Co.) were developed, and the spots were visualized under UV irradiation at wavelengths of 254 nm or 365 nm. Column chromatography was performed on silica gel 60G (particle size 5 μm to 40 μm, Merck Co.). ¹H and ¹³C{¹H} NMR spectra were collected using Bruker, Avance III-300 and 500 NMR spectrometers. Chemical shifts were referenced to tetramethylsilane. High-resolution mass spectra were acquired using JEOL, JMS-700GC or Agilent, 6890 series instruments. Elemental analyses were performed using a Thermo Fisher Scientific, Flash 2000 instrument.

### Synthesis Example 1: Synthesis of [Au(^{Dipp}PZI)(Cl)]

[Au(^{Dipp}PZI)(Cl)], which is an intermediate of the Au(I) complex according to Example 1, has been synthesized by the method described below and summarized in Scheme 1.

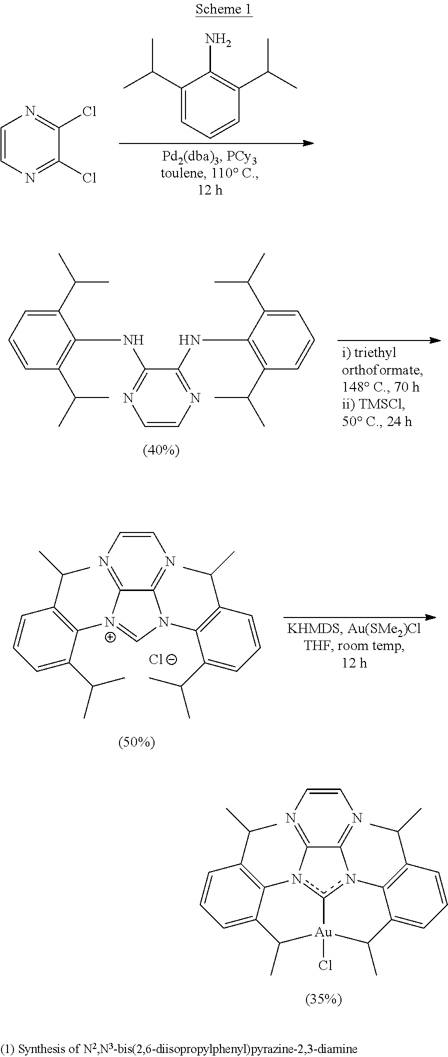

2,3-Dichloropyrazine (5.00 g, 33.6 mmol), 2,6-diisopropylaniline (17.9 g, 101 mmol), and NaO^{t}Bu (9.70 g, 101 mmol) were added to an oven-dried 250 mL two-neck round-bottom flask equipped with a condenser and magnetic stir bar. The mixtures were suspended in dry toluene (150 mL), and the mixture was purged with stream of an Ar gas for 15 min. After then, Pd₂(dba)₃ (7.68 g, 8.39 mmol) and PCy₃ (3.76 g, 13.4 mmol) dissolved in 150 mL dry toluene were added to the reaction solution. The reaction mixture was allowed to be refluxed for 15 h under an Ar atmosphere. After cooling the reaction mixture, the solvent was evaporated under a reduced pressure. The crude product was diluted with CH₂Cl₂, and filtered through a celite pad to remove solid particles. The filtrate was poured onto water, and extracted with CH₂Cl₂ (100 mL×twice). The combined organic layers were dried over anhydrous MgSO₄, filtered, and concentrated. Finally, the product was purified by silica gel column chromatography using an eluent of EtOAc:n-hexane (3:17, v/v) to afford red powders (40%). R_{f}=0.4 (EtOAc:n-hexane=1:4, v/v).

¹H NMR (300 MHz, CD₂Cl₂) δ(ppm): 7.45 (s, 2H), 7.29-7.32 (m, 2H), 7.22-7.25 (m, 4H), 5.72 (s, 2H), 3.11 (m, 4H), 1.17 (d, J=6.6 Hz, 24H).

¹³C{¹H} NMR (126 MHz, CD₂Cl₂) δ(ppm): 146.8, 144.8, 134.7, 132.5, 128.0, 124.2, 29.2, 24.1, 23.9, 23.4.

HR MS (FAB+, m-NBA): calcd for C₂₈H₃₉N₄ ([M+H]⁺), 431.3169; found, 431.3180.

### (2) Synthesis of 1,3-bis(2,6-diisopropylphenyl)-1H-imidazo[4,5-b]pyrazine-3-ium chloride

N²,N³-Bis(2,6-diisopropylphenyl)pyrazine-2,3-diamine (1.000 g, 2.32 mmol) was dissolved in 250 mL of triethylorthoformate in an oven-dried 250 mL round-bottom flask equipped with a condenser and a magnetic stir bar. The reaction mixture was heated at 150° C. for 48 hours (h). Fractional distillation apparatus was equipped to the reaction flask, and ca. 200 mL of a liquid containing ethanol formed during the condensation reaction was distilled off over the course of 4 h. After cooling the reaction solution to room temperature, 50 mL of fresh triethylorthoformate and trimethylsilyl chloride (2.52 g, 23.2 mmol) were added and the reaction mixture was stirred at 50° C. for additional 8 h. After the reaction mixtures cooled to room temperature, the solvent was removed under a reduced pressure, and the resultant solids were washed with diethyl ether to give brown solids (50%).

¹H NMR (300 MHz, CD₂Cl₂) δ(ppm): 14.14 (s, 1H), 8.88 (s, 2H), 7.73 (t, J=7.8 Hz, 2H), 7.49 (d, J=7.8 Hz, 4H), 2.1812.26 (m, 4H), 1.31 (d, J=6.6 Hz, 12H), 1.14 (d, J=6.6 Hz, 12H).

¹³C{¹H} NMR (126 MHz, CD₂Cl₂) δ(ppm): 163.5, 151.2, 151.0, 148.2, 147.0, 146.5, 146.2, 140.7, 138.2, 134.1, 133.1, 132.0, 130.4, 127.9, 126.8, 126.5, 125.4, 125.2, 124.9, 124.4, 124.2, 30.5, 30.4, 29.5, 28.9, 24.8, 24.2, 23.7.

### (3) Synthesis of [Au(^{Dipp}PZI)(Cl)]

An oven-dried 50 mL Schlenk flask was charged with 1,3-bis(2,6-diisopropylphenyl)-1H-imidazo[4,5-b]pyrazine-3-ium chloride (0.500 g, 1.05 mmol) and freshly distilled THF. 1.0 M KHMDS in THF (1.4 mL, 1.38 mmol) was dropwise added to the stirred reaction mixture, and the solution was stirred at room temperature for 1 h. Chloro(dimethylsulfido)gold(I) (0.412 g, 1.4 mmol) was added to the reaction flask. The reaction mixture was stirred at room temperature under an Ar atmosphere overnight. The reaction mixture was filtered through a layer of celite. The filtrate was collected and concentrated under a reduced pressure. Diethyl ether was poured onto the concentrated solution to afford precipitates, and brown solids were collected (35%).

¹H NMR (300 MHz, CD₂Cl₂) δ(ppm): 8.57 (s, 2H), 7.69 (t, J=7.8 Hz, 2H), 7.46 (d, J=7.8 Hz, 4H), 2.33 (m, 4H), 1.33 (d, J=6.9 Hz, 12H), 1.10 (d, J=6.9 Hz, 12H).

¹³C{¹H} NMR (126 MHz, CD₂Cl₂) δ(ppm): 188.2, 147.0, 146.9, 142.7, 142.3, 140.4, 132.3, 132.1, 130.6, 125.3, 30.0, 24.8, 24.6, 24.1.

LR MS (FAB+, m-NBA): 637 ([M-Cl]⁺) and 439 ([M-(AuCl)]⁺).

### Synthesis Example 2: Synthesis of [Au(^{Dipp}BZI)(Cl)]

[Au(^{Dipp}BZI)(Cl)], which is an intermediate of the Au(I) complexes according to Examples 2 and 3, has been synthesized by the method described below and summarized in Scheme 2.

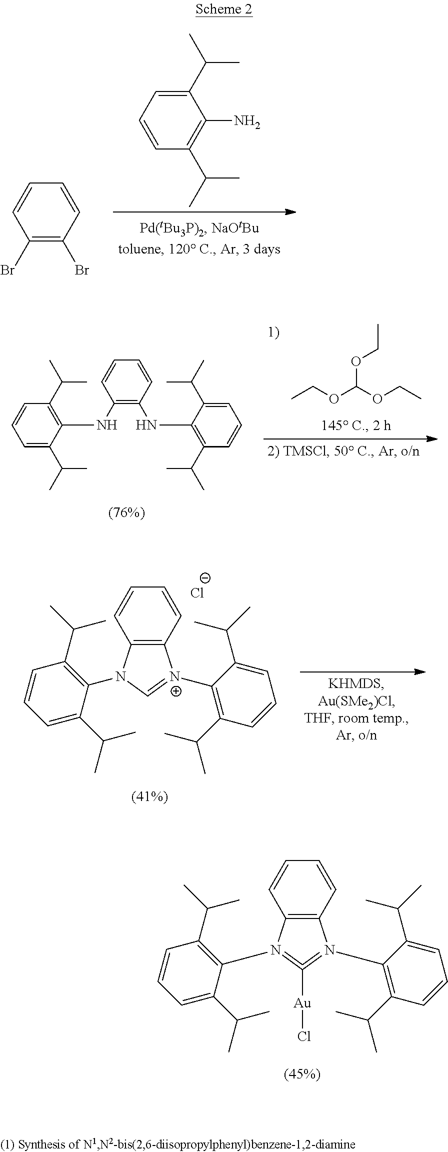

1,2-Dibromobenzene (6.70 g, 28.4 mmol), 2,6-diisopropylaniline (20.1 g, 114 mmol), and NaOtBu (10.9 g, 114 mmol) were added to an oven-dried 250 mL Schlenk flask equipped with a magnetic stir bar. The mixtures were suspended in dry toluene (140 mL), and the mixture was purged with stream of an Ar gas for 10 min. Then, Pd(^{t}Bu₃P)₂ (1.45 g, 2.84 mmol) dissolved in toluene (10 ml) was added to the reaction solution. The solution was heated at 120° C. for 3 days under an Ar atmosphere. After cooling the reaction mixture to room temperature, it was filtered through a celite pad. The solvent was removed under reduced pressure. Purification was performed by increasing the polarity of the solvent from dichloromethane:n-hexane=1:49 (v/v) to 1:19 (v/v) through silica gel column purification. Brown powder was obtained (76%). R_{f}=0.25 (EtOAc:n-hexane=1:99, v/v).

¹H NMR (300 MHz, CD₂Cl₂) δ (ppm): 1.14 (d, J=6.9 Hz, 12H), 1.22 (d, J=6.9 Hz, 12H), 3.18 (septet, J=6.9 Hz, 4H), 5.23 (s, 2H) 6.22 (dd, J=6.3, 3.0 Hz, 2H), 6.60 (dd, J=6.3, 3.0 Hz, 2H), 7.23-7.29 (m, 6H).

¹³C{¹H} NMR (126 MHz, CD₂Cl₂) δ(ppm): 23.45, 25.00, 28.77, 114.89, 120.39, 124.35, 126.69, 137.32, 137.45, 145.98.

HR MS (FAB+): Calcd for C₃₀H₄₀N₂ ([M]⁺), 428.3191. Found: 428.3194.

Anal. Calcd for C₃₀H₄₀N₂: C, 84.06; H, 9.41; N, 6.54. Found: C, 84.12; H, 9.43; N, 6.35%.

### (2) Synthesis of 1,3-bis(2,6-diisopropylphenyl)-1H-benzo[d]imidazol-3-ium chloride

N¹,N²-Bis(2,6-diisopropylphenyl)benzene-1,2-diamine (9.00 g, 21.0 mmol) and anhydrous triethyl orthoformate (HC(OEt)₃, 200 mL) were added in an 250 mL oven-dried 2-neck round-bottom flask, and the flask was connected to a fractional distillation apparatus equipped with a Vigruex column and a thermometer. The reaction mixture was fluxed for 2 h in an Ar atmosphere, during which the color of the mixture changes to green. During the reflux, a mixture of ethanol and triethyl orthoformate is fractionally distilled from the reaction mixture. After cooling the reaction mixture to 50° C., trimethylsilyl chloride (43 mL, 340 mmol) was added thereto. The reaction mixture was stirred at 50° C. for overnight, and then cooled to room temperature. The solvent was removed under a reduced pressure to obtain pale green powder. The powder was well dispersed in diethyl ether (30 mL), and washed thoroughly with diethyl ether (15 mL×3 times) to give green powder (41%).

¹H NMR (300 MHz, CD₂Cl₂) δ (ppm): 1.16 (d, J=6.9 Hz, 12H), 1.30 (d, J=6.9 Hz, 12H), 2.27 (septet, J=6.9 Hz, 4H), 7.37 (dd, J=6.3, 3.0 Hz, 2H), 7.49 (d, J=7.8 Hz 4H), 7.70 (dd, J=6.3, 3.0 Hz, 2H), 7.72 (t, J=7.8 Hz, 2H), 12.9 (s, 1H).

¹³C{¹H} NMR (126 MHz, CD₂Cl₂) δ(ppm): 23.57, 25.19, 29.89, 113.94, 125.48, 127.94, 129.06, 132.73, 133.31, 146.54, 147.07, 147.21.

HR MS (FAB+): Calcd for C₃₁H₃₉N₂ ([M]⁺), 439.3108; Found: 439.3112.

### (3) Synthesis of [Au(^{Dipp}BZI)(Cl)]

A 100 mL 2-neck round-bottomed flask equipped with a magnetic stir bar was charged with 1,3-bis(2,6-diisopropylphenyl)-1H-benzo[d]imidazol-3-ium chloride (4.00 g, 8.42 mmol) dissolved in distilled THF (40 mL). The mixture was stirred at room temperature for 5 minutes. 1.0 M KHMDS in THF (9.3 mL, 9.26 mmol) was slowly added to the stirred mixture, and the reaction mixture was stirred at room temperature for 1 h. Chloro(dimethylsulfido)gold(I) (2.48 g, 8.42 mmol) was added to the reaction mixture at dark room, and the reaction mixture was stirred at room temperature under an Ar atmosphere overnight. Color of the reaction mixture changes from red to deep purple during the reaction proceeds. After then, the solvent was removed under a reduced pressure, and n-hexane (25 mL) was added to obtain deep purple powder The powder was washed with n-hexane (10 mL×3 times) to obtain purple powder (45%).

¹H NMR (300 MHz, CD₂Cl₂) δ (ppm): 1.10 (d, J=6.9 Hz, 12H), 1.32 (d, J=6.9 Hz, 12H), 2.40 (septet, J=6.9 Hz, 4H), 7.11 (dd, J=6.2, 3.0 Hz, 2H), 7.44 (dd, J=6.2, 3.0 Hz, 2H), 7.44 (d, J=7.8 Hz, 4H), 7.66 (t, J=7.8 Hz, 2H).

¹³C{¹H} NMR (126 MHz, CD₂Cl₂) δ(ppm): 24.16, 24.92, 29.48, 112.62, 125.25, 126.09, 131.60, 131.81, 135.08, 147.15, 182.07.

Anal. Calcd for C₃₁H₃₈AuClN₂: C, 55.48; H, 5.71; N, 4.17. Found: C, 55.86; H, 5.76; N, 4.12%.

### Synthesis Example 3: Synthesis of [Au(^{Dtbp}Im)(Cl)]

[Au(^{Dtbp}Im)(Cl)], which is an intermediate of the Au(I) complexes according to Examples 11 and 12, has been synthesized by the method described below and summarized in Scheme 3.

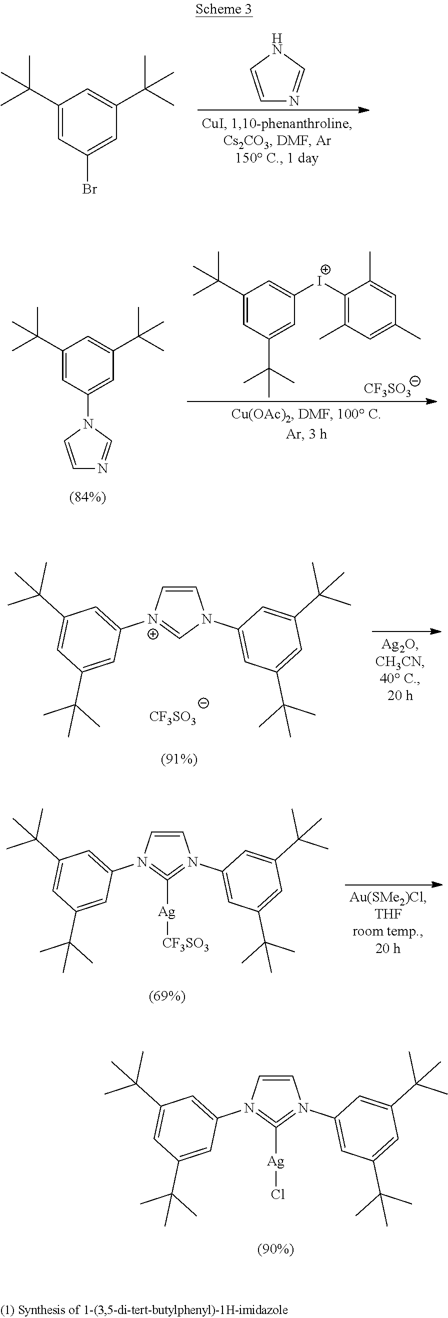

1-bromo-3,5-di-tert-butylbenzene (3.00 g, 11.1 mmol), imidazole (1.06 g, 15.5 mmol), CuI (0.42 g, 2.2 mmol), 1,10-phenanthroline (0.40 g, 2.2 mmol), and cesium carbonate (7.24 g, 22.2 mmol) were placed in a 100 mL round-bottomed flask, and 50 mL of anhydrous dimethylformamide was added. Then, the reaction mixture was refluxed with stirring at 150° C. for one day in an Ar atmosphere. After cooling the reaction mixture to room temperature, it was diluted by adding 100 mL of ethyl acetate, and filtered through a Celite pad. The obtained filtrate is dried under reduced pressure, and then purified through silica gel column purification by increasing the polarity of the solvent from ethyl acetate:n-hexane=1:19 (v/v) to 1:9 (v/v). White powder was obtained with an 84% yield.

¹H NMR (300 MHz, CD₂Cl₂) δ (ppm): 1.35 (s, 18H), 7.14 (s, 1H), 7.22 (s, 2H), 7.31 (t, J=1.2 Hz, 1H), 7.45 (t, J=1.8 Hz, 1H), 7.81 (s, 1H).

¹³C{¹H} NMR (126 MHz, CD₂Cl₂) δ(ppm): 31.63, 35.53, 116.87, 119.21, 122.23, 130.37, 136.38, 137.65, 153.44.

### (2) Synthesis of 1,3-bis(3,5-di-tert-butylphenyl)-1H-imidazol-3-ium trifluoromethanesulfonate

1-(3,5-di-tert-butylphenyl)-1H-imidazole (2.39 g, 9.3 mmol), (3,5-di-ter-butylphenyl)(methyl)iodonium trifluoromethanesulfonate (8.18 g, 14.0 mmol), and Cu(OAc)₂ (0.16 g, 1 mmol) were placed in a 100 mL round-bottomed flask, and 50 mL of anhydrous dimethylformamide was added thereto. The mixture was heated at 100° C. for 3 hours with stirring in an Ar atmosphere. The mixture was cooled to room temperature and filtered through a Celite pad. The obtained filtrate was dried under reduced pressure, and then purified through silica gel column purification by the polarity of the solvent of ethyl acetate:n-hexane=1:9 (v/v). White powder was obtained in 91% yield.

¹H NMR (300 MHz, CD₂Cl₂) δ (ppm): 1.40 (s, 36H), 7.46 (s, 4H), 7.70 (t, J=1.8 Hz, 2H), 7.84 (s, 2H), 9.24 (s, 1H).

¹³C{¹H} NMR (126 MHz, CD₂Cl₂) δ(ppm): 31.48, 35.82, 118.05, 123.71, 125.81, 133.63, 134.77, 154.68.

### (3) Synthesis of [Ag(^{Dtbp}Im)(CF₃SO₃)]

1,3-bis(3,5-di-ter-butylphenyl)-1H-imidazole-3-ium trifluoromethanesulfonate (5.03 g, 8.4 mmol), and silver oxide (0.97 g, 4.2 mmol) were placed in a 100 mL round-bottomed flask, and 50 mL of anhydrous acetonitrile was added thereto. The mixture was heated at 40° C. for 20 hours with stirring in an Ar atmosphere. The color of the solution changes from black to yellow. The mixture was cooled, added with n-hexane, and filtered to filter out the resulting precipitate. The precipitate was washed several times with n-hexane, and dried in a vacuum oven. White powder was obtained with a 69% yield.

¹H NMR (300 MHz, CD₂Cl₂) δ (ppm): 1.21 (s, 36H), 7.35 (s, 4H), 7.48 (t, J=1.8 Hz, 2H), 7.56 (s, 2H).

¹³C{¹H} NMR (126 MHz, CD₂Cl₂) δ(ppm): 31.58, 35.52, 117.95, 123.06, 123.11, 123.73, 139.81, 153.73.

### (4) Synthesis of [Au(^{Dtbp}Im)(Cl)]

[Au(^{Dtbp}Im)(CF₃SO₃)] (4.07 g, 5.8 mmol) and Au(SMe₂)(Cl) (1.71 g, 5.8 mmol) were placed in a 100 mL round-bottomed flask, and added with 50 mL of anhydrous tetrahydrofuran. The mixture was stirred at room temperature for 20 hours in an Ar atmosphere while blocking light. After removing the solvent under reduced pressure, n-hexane (25 mL) was added to form a dark purple powder, which was washed several times with n-hexane (10 mL×3 times) to obtain a purple powder in 90% yield.

¹H NMR (300 MHz, CD₂Cl₂) δ (ppm): 1.22 (s, 36H), 7.44 (s, 4H), 7.48 (t, J=1.8 Hz, 2H), 7.51 (s, 2H).

¹³C{¹H} NMR (126 MHz, CD₂Cl₂) δ(ppm): 31.59, 35.52, 118.74, 123.20, 123.79, 139.02, 153.43, 180.24.

### Example 1: Synthesis of [Au(^{Dipp}PZI)(ACD)]

To a flame-dried round-bottom flask, 9(10H)-acridone (0.072 g, 0.37 mmol) was added and dissolved in dry THF (10 mL). NatBuO (0.046 g, 0.48 mmol) was added to the stirred solution, and stirred for 0.5 h under an Ar atmosphere. [Au(^{Dipp}PZI)(Cl)](0.250 g, 0.37 mmol) prepared in Synthesis Example 1 was subsequently added to the reaction mixture, which was stirred at room temperature for additional 12 h under dark. The reaction solution was diluted with 25 mL CH₂Cl₂, and filtered through Celite pad. The filtrate was concentrated under a reduced pressure. The addition of 13 mL of CH₂Cl₂:diethyl ether (3:10, v/v) yielded yellow powders. Finally, purification by recrystallization in CH₂Cl₂ and n-pentane afforded 0.220 g of single crystals (72%).

¹H NMR (300 MHz, CD₂Cl₂) δ(ppm): 8.65 (s, 2H), 8.27 (dd, J=8.4 and 1.8 Hz, 4H), 7.86 (t, J=7.8 Hz, 2H), 7.58 (d, J=7.8 Hz, 4H), 7.12 (dt, J=6.6 and 1.5 Hz, 2H), 6.94-7.00 (m, 4H), 2.47 (m, 4H), 1.30 (d, J=6.9 Hz, 12H), 1.17 (d, J=6.9 Hz, 12H).

¹³C{¹H} NMR (126 MHz, CD₂Cl₂) δ (ppm): 189.8, 177.8, 150.6, 147.6, 142.3, 140.7, 133.7, 132.2, 131.4, 131.0, 127.2, 126.7, 125.4, 125.3, 123.3, 122.7, 121.5, 119.7, 117.7, 30.2, 24.5, 24.4.

HR MS (FAB+, m-NBA): calcd for C₄₂H₄₅AuN₅O ([M+H]⁺), 832.3284; found, 832.3282. Anal. Calcd for C₄₂H₄₄AuN₅O: C, 60.65; N, 8.42; H, 5.33. Found: C, 60.84; N, 8.30; H, 5.24%.

From the ¹H NMR, ¹³C{¹H} NMR, and HR MS results, the obtained single crystals are confirmed to be a gold complex [Au(^{Dipp}PZI)(ACD)], which is represented by the following chemical formula, in which 9(10H)-acridone is coordinated to gold atom instead of chloride in Au(^{Dipp}PZI)(Cl).

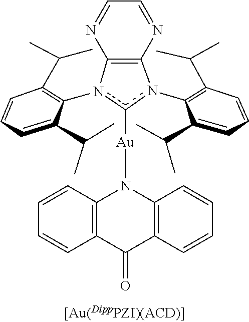

### Example 2: Synthesis of [Au(^{Dipp}BZI)(CNCz)]

9H-carbazole-3,6-dicarbonitrile (0.371 g, 1.71 mmol), [Au(^{Dipp}BZI)(Cl)] (1.200 g, 1.79 mmol) prepared in Synthesis Example 2, and NatBuO (0.210 g, 2.15 mmol) were suspended in freshly distilled THF (50 mL) in a 100 mL two-necked round-bottom flask, which was flame-dried, equipped with a magnetic stir bar. The mixture was stirred overnight at room temperature in the absence of light and under an Ar atmosphere. The solvent was removed under reduced pressure. Hexane was added, and the precipitate was subsequently triturated. The resultant was washed with hexane to afford white powder (26%).

¹H NMR (300 MHz, CD₂Cl₂) δ (ppm): 8.25 (s, 2H), 7.78 (t, J=7.8 Hz, 2H), 7.45-7.60 (m, 6H), 7.37 (d, J=8.4 Hz, 2H), 7.20-7.31 (m, 2H), 6.69 (d, J=8.4 Hz, 2H), 2.51 (septet, J=6.9 Hz, 4H), 1.30 (d, J=6.9 Hz, 12H), 1.16 (d, J=6.6 Hz, 12H). ¹³C{¹H} NMR (126 MHz, CD₂Cl₂) δ(ppm): 152.6, 147.7, 135.4, 132.0, 131.7, 128.5, 126.3, 125.5, 125.3, 125.2, 123.7, 121.6, 115.2, 112.7, 100.1, 29.7, 29.5, 25.0, 24.4, 24.2.

From the ¹H NMR and ¹³C{¹H} NMR results, the obtained white powder is confirmed to be a gold complex [Au(^{Dipp}BZI)(CNCz)], which is represented by the following chemical formula, in which 9H-carbazole-3,6-dicarbonitrile is coordinated to gold atom instead of chloride in Au(^{Dipp}BZI)(Cl).

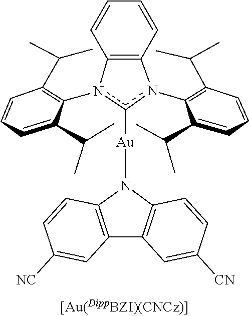

### Example 3: Synthesis of [Au(^{Dipp}BZI)(Cz3)]

[Au(^{Dipp}BZI)(Cz3)] was prepared by the same method as Example 2 for preparing [Au(^{Dipp}BZI)(CNCz)], except for using 9′H-9,3′:6′,9″-tercarbazole (0.184 g, 0.37 mmol) instead of 9H-carbazole-3,6-dicarbonitrile. Purification by recrystallization with CH₂Cl₂ and pentane gave white crystalline solid (41%).

¹H NMR (300 MHz, CD₂Cl₂) δ (ppm): 8.13 (d, J=6.9 Hz, 4H), 8.03 (s, 2H), 7.75 (s, 1H), 7.72 (d, J=7.8 Hz, 2H), 7.45-7.60 (m, 6H), 7.15-7.43 (m, 15H), 2.61 (septet, J=6.9 Hz, 4H), 1.44 (d, J=6.6 Hz, 12H), 1.19 (d, J=6.9 Hz, 12H).

¹³C{¹H} NMR (126 MHz, CD₂Cl₂) δ (ppm): 185.1, 150.0, 147.7, 142.8, 135.5, 132.2, 131.7, 126.8, 126.4, 126.1, 126.1, 125.3, 124.7, 124.3, 123.3, 120.7, 120.5, 120.2, 120.1, 119.7, 119.3, 115.2, 112.6, 110.5, 110.3, 68.3, 29.7, 26.1, 25.0, 24.4.

From the ¹H NMR and ¹³C{¹H} NMR results, the obtained white crystalline solid is confirmed to be a gold complex [Au(^{Dipp}BZI)(Cz3)], which is represented by the following chemical formula, in which 9′H-9,3′:6′,9″-tercarbazole is coordinated to gold atom instead of chloride in Au(^{Dipp}BZI)(Cl).

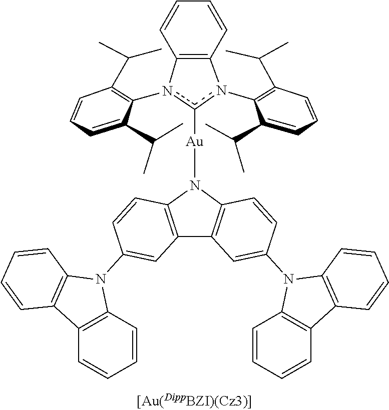

### Example 4: Synthesis of [Au(^{Dipp}Im)(CZ)]

9H-carbazole (0.048 g, 0.29 mmol), [Au(^{Dipp}Im)(Cl)] (0.150 g, 0.24 mmol) purchased from Tokyo Chemical Industry Co. Ltd., (TCI), and NatBuO (0.025 g, 0.26 mmol) were suspended in freshly distilled THF (24 mL) in a 50 mL two-necked round-bottom flask, which was flame-dried, equipped with a magnetic stir bar. The mixture was stirred overnight at room temperature in the absence of light and under an Ar atmosphere. The solvent was removed under reduced pressure. Mixed solvent of Dichloromethane and n-hexane was added and the precipitate was collected as white powder (60%).

¹H NMR (300 MHz, CD₂Cl₂) δ(ppm): 7.88 (ddd, J=7.7, 1.3, 0.7 Hz, 2H), 7.65 (dd, J=8.2, 7.4 Hz, 2H), 7.43 (d, J=7.8 Hz, 4H), 7.35 (s, 2H), 7.02 (ddd, J=8.3, 7.0, 1.3 Hz, 2H), 6.85 (ddd, J=7.9, 7.0, 1.1 Hz, 2H), 6.72 (dt, J=8.1, 0.9 Hz, 2H), 2.72 (hept, J=6.9 Hz, 4H), 1.38 (d, J=6.9 Hz, 12H), 1.28 (d, J=6.9 Hz, 12H).

¹³C{¹H} NMR (126 MHz, CD₂Cl₂) δ (ppm): 179.18, 149.91, 146.72, 134.90, 131.18, 124.79, 124.01, 123.92, 123.87, 119.63, 116.14, 113.99, 29.53, 24.73, 24.45.

HR MS (FAB+): Calcd for C₃₉H₄₄AuN₃, 751.32; Found: 751.3201. Anal. Calcd for C₃₉H₄₄AuN₃: C, 62.31; H, 5.90; N, 5.59. Found: C, 59.89; H, 5.81; N, 5.26.

From the ¹H NMR, ¹³C{¹H} NMR, and HR MS results, the obtained white powder is confirmed to be a gold complex [Au(^{Dipp}Im)(Cz)], which is represented by the following chemical formula, in which 9H-carbazole is coordinated to gold atom instead of chloride in Au(^{Dipp}Im)(Cl).

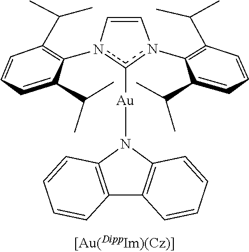

### Example 5: Synthesis of [Au(^{Dipp}Im)(CNCz)]

[Au(^{Dipp}Im)(CNCz)] was prepared by the same method as Example 4 for preparing [Au(^{Dipp}Im)(Cz)], except for using 9H-carbazole-3,6-dicarbonitrile (0.063 g, 0.29 mmol) instead of 9H-carbazole. Purification by recrystallization with CH₂Cl₂ and n-hexane gave white crystalline solid (60%).

¹H NMR (300 MHz, CD₂Cl₂) δ (ppm): 8.23 (dd, J=1.7, 0.7 Hz, 2H), 7.73-7.62 (m, 2H), 7.44 (d, J=7.8 Hz, 4H), 7.42-7.30 (m, 4H), 6.69 (dd, J=8.5, 0.7 Hz, 2H), 2.67 (hept, J=6.8 Hz, 4H), 1.31 (dd, J=14.5, 6.9 Hz, 24H).

¹³C{1H} NMR (126 MHz, CD₂Cl₂) δ (ppm): 177.01, 152.58, 146.74, 134.61, 131.39, 128.37, 125.47, 124.90, 124.24, 123.62, 121.63, 115.17, 99.96, 29.52, 24.76, 24.42.

HR MS (FAB+): Calcd for C₄₁H₄₂AuN₅, 801.31; Found: 802.3183 [M+H]⁺.

Anal. Calcd for C₄₁H₄₂AuN₅: C, 61.42; H, 5.28; N, 8.73. Found: C, 63.97; H, 5.11; N, 10.16.

From the ¹H NMR, ¹³C{¹H} NMR, and HR MS results, the obtained white crystalline solid is confirmed to be a gold complex [Au(^{Dipp}Im)(CNCz)], which is represented by the following chemical formula, in which 9H-carbazole-3,6-dicarbonitrile is coordinated to gold atom instead of chloride in Au(^{Dipp}Im)(Cl).

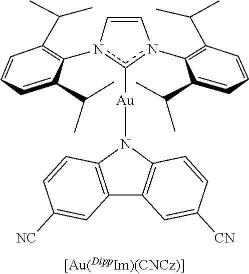

### Example 6: Synthesis of [Au(^{Dipp}Im)(Cz3)]

[Au(^{Dipp}Im)(Cz3)] was prepared by the same method as Example 4 for preparing [Au(^{Dipp}Im)(Cz)], except for using 9′H-9,3′:6′,9″-tercarbazole (0.129 g, 0.29 mmol) instead of 9H-carbazole. Purification by recrystallization with CH₂Cl₂ and n-hexane gave white crystalline solid (75%).

¹H NMR (300 MHz, CD₂Cl₂) δ(ppm): 8.12 (d, J=6.9 Hz, 4H), 8.01 (d, J=1.5 Hz, 2H), 7.63 (t, J=9.0 Hz, 2H), 7.46 (d, J=7.8 Hz, 4H), 7.41 (s, 2H), 7.36 (dd, J=1.2 and 6.6 Hz, 2H), 7.33 (dd, J=1.2 and 6.9 Hz, 2H), 7.25-7.31 (m, 4H), 7.15-7.31 (m, 6H), 7.96 (d, J=8.1 Hz, 2H), 2.77 (pentet, J=6.9 Hz, 4H), 1.46 (d, J=6.9 Hz, 12H), 1.31 (d, J=6.9 Hz, 12H).

¹³C{¹H} NMR (126 MHz, CD₂Cl₂) δ (ppm): 178.40, 149.98, 146.78, 142.78, 134.84, 131.31, 126.67, 126.14, 124.89, 124.64, 124.18, 124.10, 123.27, 120.71, 120.48, 119.65, 119.27, 115.19, 110.54, 110.28, 29.59, 24.87, 24.47.

HR MS (FAB+): Calcd for C₆₃H₅₈AuN₅, 1081.44; Found: 1081.4366. Anal. Calcd for C₆₃H₅₈AuN₅: C, 69.92; H, 5.40; N, 6.47. Found: C, 66.38; H, 5.38; N, 5.95.

From the ¹H NMR, ¹³C{¹H} NMR, and HR MS results, the obtained white crystalline solid is confirmed to be a gold complex [Au(^{Dipp}Im)(Cz3)], which is represented by the following chemical formula, in which 9′H-9,3′:6′,9″-tercarbazole is coordinated to gold atom instead of chloride in Au(^{Dipp}Im)(Cl).

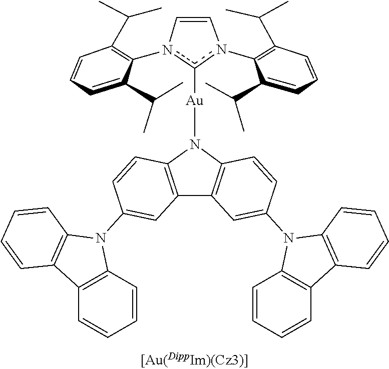

### Example 7: Synthesis of [Au(^{Dipp}Im)(αCb)]

[Au(^{Dipp}Im)(αCb)] was prepared by the same method as Example 4 for preparing [Au(^{Dipp}Im)(Cz)], except for using 9H-pyrido[2,3-b]indole (0.049 g, 0.29 mmol) instead of 9H-carbazole. Purification by recrystallization with CH₂Cl₂ and n-hexane gave white solid (60%).

¹H NMR (300 MHz, CD₂Cl₂) δ (ppm): 8.21-8.08 (m, 2H), 7.87 (ddd, J=7.7, 1.3, 0.8 Hz, 1H), 7.59 (dd, J=8.2, 7.4 Hz, 2H), 7.39 (d, J=7.8 Hz, 4H), 7.32 (s, 2H), 7.08 (ddd, J=8.3, 7.1, 1.4 Hz, 1H), 6.97-6.86 (m, 1H), 6.85-6.71 (m, 2H), 2.74 (hept, J=6.9 Hz, 4H), 1.42 (s, 12H), 1.27 (d, J=6.9 Hz, 12H).

¹³C{¹H} NMR (126 MHz, CD₂Cl₂) δ (ppm): 178.47, 160.71, 149.42, 146.63, 145.49, 134.98, 131.11, 126.94, 126.92, 124.80, 124.76, 124.04, 122.31, 120.25, 116.97, 116.56, 114.37, 112.40, 29.54, 29.36, 24.68, 24.41.

HR MS (FAB+): Calcd for C₃₈H₄₃AuN₄, 752.32; Found: 753.3281 [M+H]⁺. Anal. Calcd for C₄₁H₄₂AuN₅: C, 60.63; H, 5.76; N, 7.44. Found: C, 60.73; H, 5.77; N, 7.41.

From the ¹H NMR, ¹³C{¹H} NMR, and HR MS results, the obtained white solid is confirmed to be a gold complex [Au(^{Dipp}Im)(αCb)], which is represented by the following chemical formula, in which 9H-pyrido[2,3-b]indole is coordinated to gold atom instead of chloride in Au(^{Dipp}Im)(Cl).

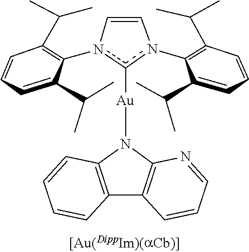

### Example 8: Synthesis of [Au(^{Dipp}Im)βCb)]

[Au(^{Dipp}Im)(βCb)] was prepared by the same method as Example 4 for preparing [Au(^{Dipp}Im)(Cz)], except for using 9H-pyrido[3,4-b]indole (0.049 g, 0.29 mmol) instead of 9H-carbazole. Purification by recrystallization with CH₂Cl₂ and n-hexane gave white solid (68%).

¹H NMR (300 MHz, CD₂Cl₂) δ (ppm): 8.13 (d, J=1.1 Hz, 1H), 8.02 (d, J=5.2 Hz, 1H), 7.96 (ddd, J=7.8, 1.2, 0.7 Hz, 1H), 7.76 (dd, J=5.2, 1.1 Hz, 1H), 7.72-7.61 (m, 2H), 7.44 (d, J=7.8 Hz, 4H), 7.37 (s, 2H), 7.16 (ddd, J=8.3, 7.0, 1.3 Hz, 1H), 6.93 (ddd, J=7.9, 7.0, 1.0 Hz, 1H), 6.77 (dt, J=8.3, 0.9 Hz, 1H), 2.71 (hept, J=7.0 Hz, 4H), 1.38 (d, J=6.9 Hz, 12H), 1.28 (d, J=6.9 Hz, 12H).

¹³C{¹H} NMR (126 MHz, CD₂Cl₂) δ (ppm): 178.30, 150.74, 146.68, 146.33, 146.03, 139.57, 137.41, 137.39, 135.87, 135.85, 134.77, 131.31, 131.25, 128.43, 126.27, 124.85, 124.05, 123.86, 122.26, 121.24, 117.05, 115.31, 114.16, 29.53, 29.36, 24.78, 24.72, 24.43, 24.29.

HR MS (FAB+): Calcd for C₃₈H₄₃AuN₄, 752.32; Found: 753.3237 [M+H]⁺. Anal. Calcd for C₄₁H₄₂AuN₅: C, 60.63; H, 5.76; N, 7.44. Found: C, 60.03; H, 5.64; N, 7.18.

From the ¹H NMR, ¹³C{¹H} NMR, and HR MS results, the obtained white solid is confirmed to be a gold complex [Au(^{Dipp}Im)(βCb)], which is represented by the following chemical formula, in which 9H-pyrido[3,4-b]indole is coordinated to gold atom instead of chloride in Au(^{Dipp}Im)(Cl).

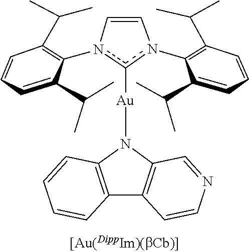

### Example 9: Synthesis of [Au(^{Dipp}Im)(γCb)]

[Au(^{Dipp}Im)(γCb)] was prepared by the same method as Example 4 for preparing [Au(^{Dipp}Im)(Cz)], except for using 5H-pyrido[4,3-b]indole (0.049 g, 0.29 mmol) instead of 9H-carbazole. Purification by recrystallization with CH₂Cl₂ and n-hexane gave white solid (66%).

¹H NMR (300 MHz, CD₂Cl₂) δ (ppm): 9.04 (s, 1H), 8.04 (d, J=5.8 Hz, 1H), 7.94 (d, J=7.7 Hz, 1H), 7.65 (t, J=7.8 Hz, 2H), 7.43 (d, J=7.8 Hz, 4H), 7.37 (s, 2H), 7.16-7.05 (m, 1H), 7.03-6.92 (m, 1H), 6.75 (dt, J=8.0, 0.9 Hz, 1H), 6.53 (d, J=5.8 Hz, 1H), 2.70 (p, J=6.9 Hz, 4H), 1.37 (d, J=6.9 Hz, 12H), 1.28 (d, J=6.9 Hz, 12H).

¹³C{¹H} NMR (126 MHz, CD₂Cl₂) δ (ppm): 178.19, 153.27, 149.98, 146.70, 146.33, 142.98, 142.30, 134.76, 131.29, 125.06, 124.83, 124.43, 124.07, 122.82, 121.35, 120.01, 118.05, 114.48, 109.05, 29.52, 29.36, 24.76, 24.43, 24.29.

HR MS (FAB+): Calcd for C₃₈H₄₃AuN₄, 752.32; Found: 753.3231 [M+H]⁺. Anal. Calcd for C₄₁H₄₂AuN₅: C, 60.63; H, 5.76; N, 7.44. Found: C, 60.93; H, 5.74; N, 7.37.

From the ¹H NMR, ¹³C{¹H} NMR, and HR MS results, the obtained white solid is confirmed to be a gold complex [Au(^{Dipp}Im)(γCb)], which is represented by the following chemical formula, in which 5H-pyrido[4,3-b]indole is coordinated to gold atom instead of chloride in Au(^{Dipp}Im)(Cl).

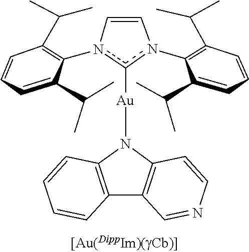

### Example 10: Synthesis of [Au(^{Dipp}Im)(δCb)]

[Au(^{Dipp}Im)(δCb)] was prepared by the same method as Example 4 for preparing [Au(^{Dipp}Im)(Cz)], except for using 5H-pyrido[3,2-b]indole (0.049 g, 0.29 mmol) instead of 9H-carbazole. Purification by recrystallization with CH₂Cl₂ and n-hexane gave white solid (70%).

¹H NMR (300 MHz, CD₂Cl₂) δ(ppm): 8.18 (dd, J=4.4, 1.7 Hz, 1H), 8.09 (ddd, J=7.7, 1.3, 0.8 Hz, 1H), 7.71-7.60 (m, 2H), 7.43 (d, J=7.8 Hz, 4H), 7.36 (s, 2H), 7.13 (ddd, J=8.3, 7.0, 1.3 Hz, 1H), 7.02-6.87 (m, 3H), 6.74 (dt, J=8.2, 0.9 Hz, 1H), 2.70 (hept, J=7.0 Hz, 4H), 1.37 (d, J=6.9 Hz, 12H), 1.28 (d, J=6.9 Hz, 12H).

¹³C{1H} NMR (126 MHz, CD₂Cl₂) δ (ppm): 178.56, 150.67, 146.71, 143.10, 142.69, 139.05, 134.80, 131.23, 125.78, 124.81, 124.01, 123.21, 120.04, 119.91, 118.68, 117.11, 114.98, 29.51, 24.75, 24.43.

HR MS (FAB+): Calcd for C₃₈H₄₃AuN₄, 752.32; Found: 753.3228 [M+H]⁺.

Anal. Calcd for C₃₈H₄₃AuN₄: C, 60.63; H, 5.76; N, 7.44. Found: C, 60.79; H, 5.73; N, 7.37.

From the ¹H NMR, ¹³C{¹H} NMR, and HR MS results, the obtained white solid is confirmed to be a gold complex [Au(^{Dipp}Im)(δCb)], which is represented by the following chemical formula, in which 5H-pyrido[3,2-b]indole is coordinated to gold atom instead of chloride in Au(^{Dipp}Im)(Cl).

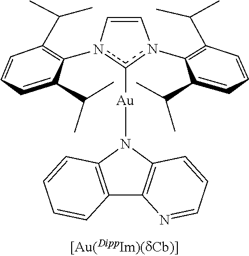

### Example 11: Synthesis of [Au(^{Dtbp}Im)(Cz)]

[Au(^{Dtbp}Im)(Cz)] was prepared by the same method as Example 4 for preparing [Au(^{Dipp}Im)(Cz)], except for using [Au(^{Dtbp}Im)(Cl)] (0.163 g, 0.24 mmol) prepared in Synthesis Example 3, instead of [Au(^{Dipp}Im)(Cl)]. Purification by recrystallization with CH₂Cl₂ and n-pentane gave white solid (25%).

¹H NMR (300 MHz, CD₂Cl₂) δ (ppm): 8.39 (d, J=1.2 Hz, 2H), 7.85 (s, 2H), 7.75 (t, J=1.8 Hz, 2H), 7.72 (d, J=1.8 Hz, 4H), 7.34 (dd, J=1.8 and 8.7 Hz, 2H), 7.07 (d, J=8.7 Hz, 2H), 1.38 (s, 36H).

¹³C{¹H} NMR (126 MHz, CD₂Cl₂) δ (ppm): 174.1, 153.5, 150.0, 139.7, 124.2, 124.1, 123.9, 122.9, 120.5, 119.7, 116.2, 114.5, 35.6, 31.7.

From the ¹H NMR, and ¹³C{¹H} NMR results, the obtained white solid is confirmed to be a gold complex [Au(^{Dtbp}Im)(Cz)], which is represented by the following chemical formula, in which 9H-carbazole is coordinated to gold atom instead of chloride in Au(^{Dtbp}Im)(Cl).

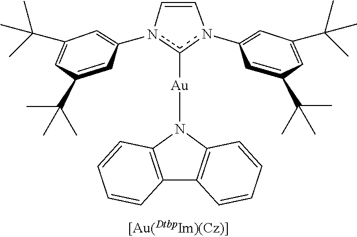

### Example 12: Synthesis of [Au(^{Dtbp}Im)(CNCz)]

[Au(^{Dtbp}Im)(Cz)] was prepared by the same method as Example 5 for preparing [Au(^{Dipp}Im)(CNCz)], except for using [Au(^{Dtbp}Im)(Cl)] (0.163 g, 0.24 mmol) prepared in Synthesis Example 3, instead of [Au(^{Dipp}Im)(Cl)]. Purification by recrystallization with CH₂Cl₂ and n-pentane gave white solid (20%).

¹H NMR (300 MHz, CD₂Cl₂) δ(ppm): 7.93 (d, J=7.8 Hz, 2H), 7.70 (dd, J=1.5 and 12 Hz, 4H), 7.64 (s, 2H), 7.47 (s, 2H), 6.9-7.1 (m, 4H), 6.88 (dd, J=1.2 and 7.8 Hz, 2H), 1.39 (s, 36H).

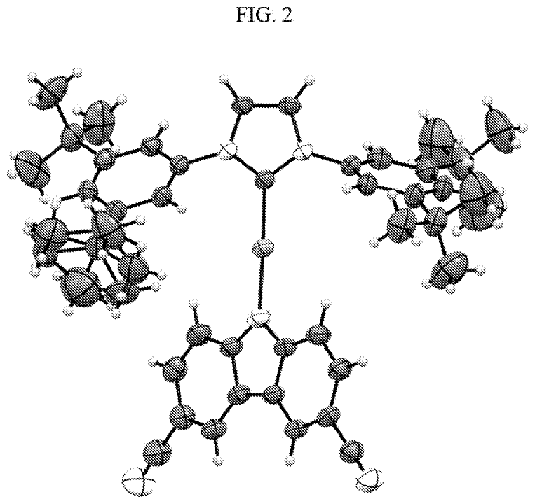

Further, the single crystalline structure of the white solid was confirmed by X-ray diffraction (XRD) analysis, and the result is shown in FIG. 2.

From the H NMR and XRD results, the obtained white solid is confirmed to be a gold complex [Au(^{Dtbp}Im)(CNCz)], which is represented by the following chemical formula, in which 9H-carbazole-3,6-dicarbonitrile is coordinated to gold atom instead of chloride in Au(^{Dtbp}Im)(Cl).

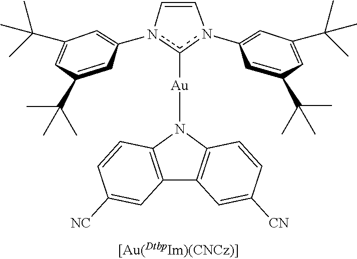

### Evaluation and Characterization of Au(I) Complexes

The gold (Au(I)) complexes according to Examples 1 to 12 have been characterized by the following methods.

### 1. X-Ray Crystallography

Single crystals suitable for X-ray crystallographic analysis were grown by layering pentane or hexane on top of dichloromethane containing the Au(I) complexes, or by diffusion of diethyl ether vapor at room temperature. A single crystal was picked up from the solution and mounted on a Bruker SMART CCD diffractometer equipped with a graphite-monochromated Mo Kα (λ=0.71073 Å) radiation source under nitrogen cold stream at 223 K. The CCD data collected and integrated by using a Bruker-SAINT software program. Semi-empirical absorption corrections based on equivalent reflections were applied by Bruker SADABS. Structures were solved and refined using SHELXL97. Hydrogen atoms were placed on the geometrically ideal positions. All non-hydrogen atoms were refined anisotropic thermal parameters.

Crystal data for [Au(^{Dipp}PZI)(ACD)] according to Example 1 are as follows:

C₄₂H₄₄AuN₅O, monoclinic, P2₁/n, Z=4, a(Å)=15.218(3), b(Å)=14.128(3), c(Å)=19.271(4), α=90°, β=111.515(6)°, γ=90°, V(Å³)=3854.5(15), μ=3.854 mm⁻¹, ρcalcd=1.433 Mg/m³, R₁=0.0225, wR₂=0.0500 for 9595 unique reflections and 450 variables.

### 2. Photoluminescence Characteristics

### (1) Steady-State UV-Vis Absorptions

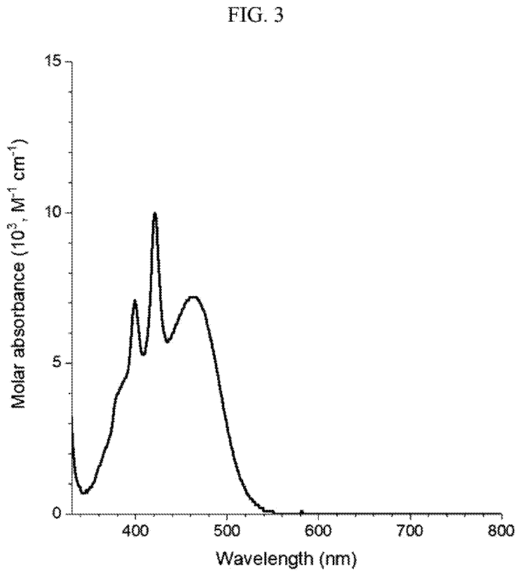

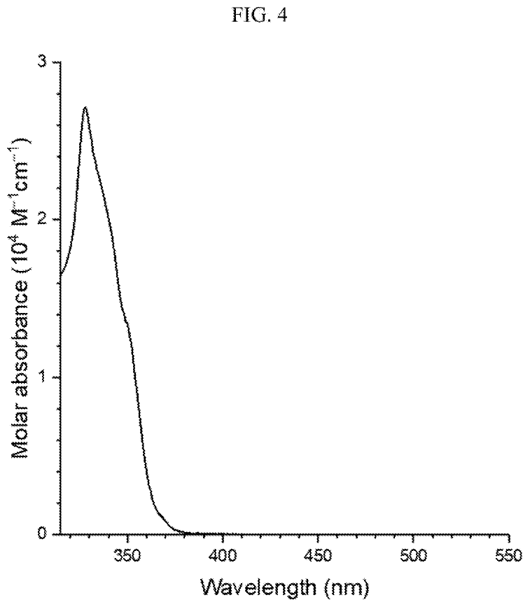

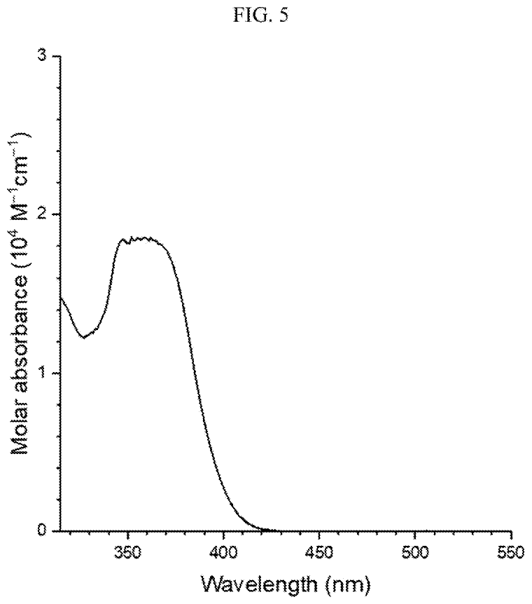

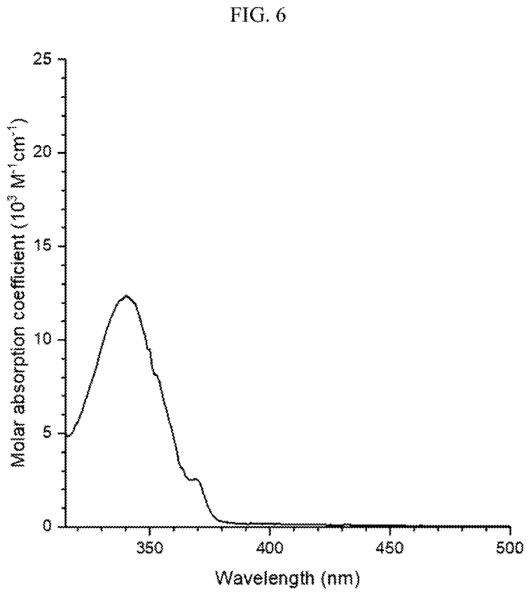

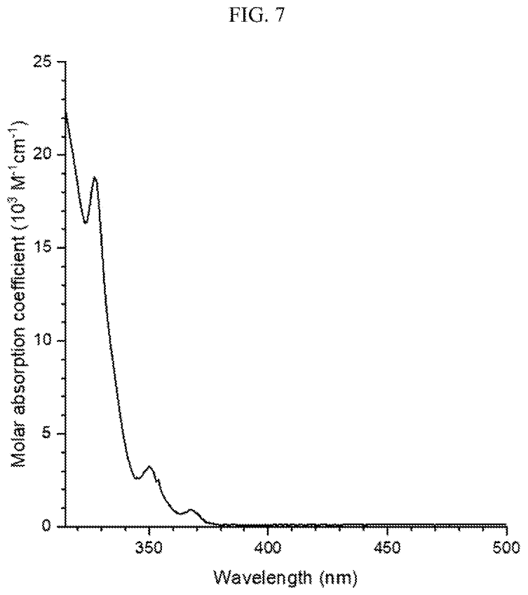

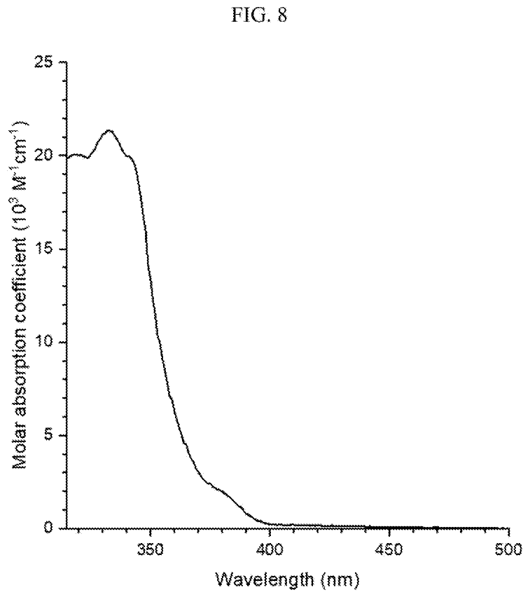

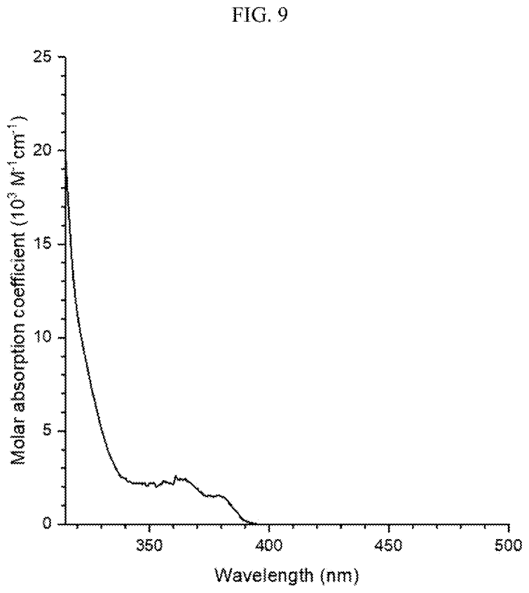

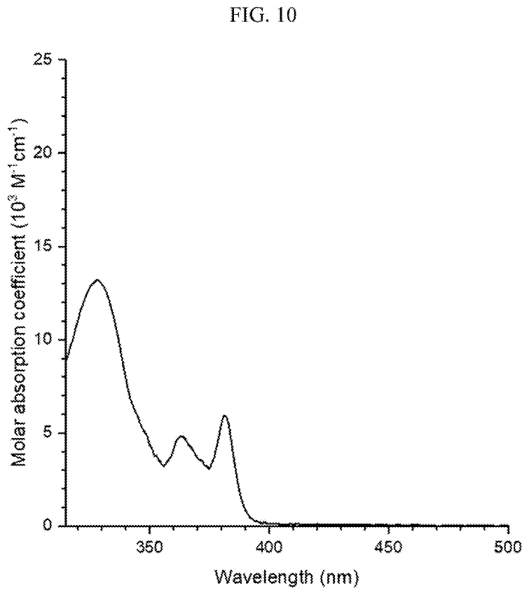

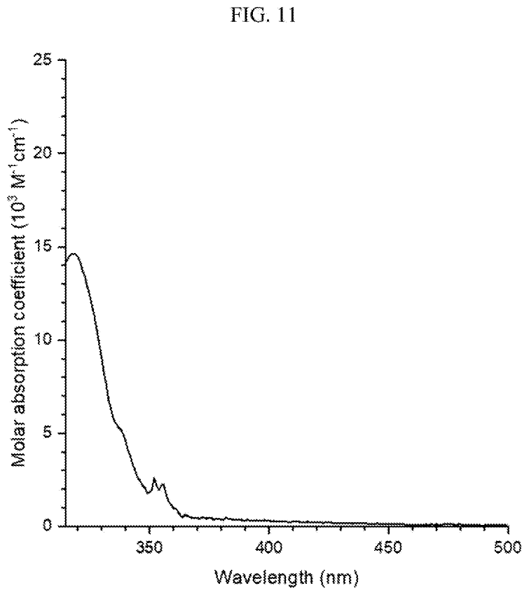

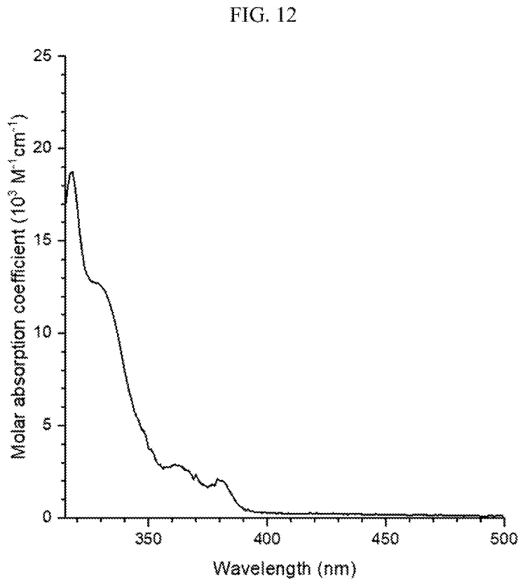

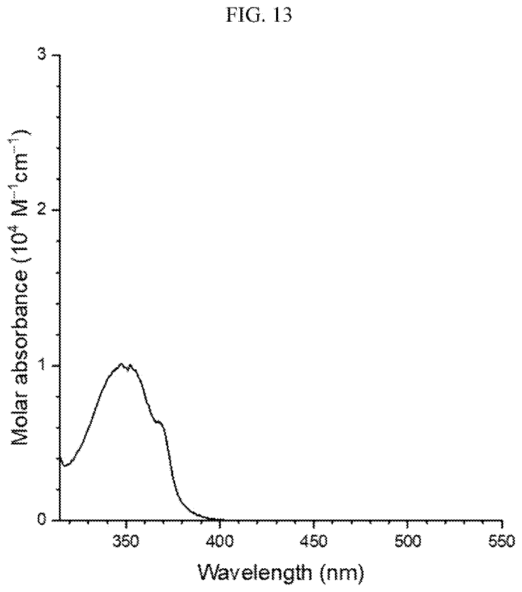

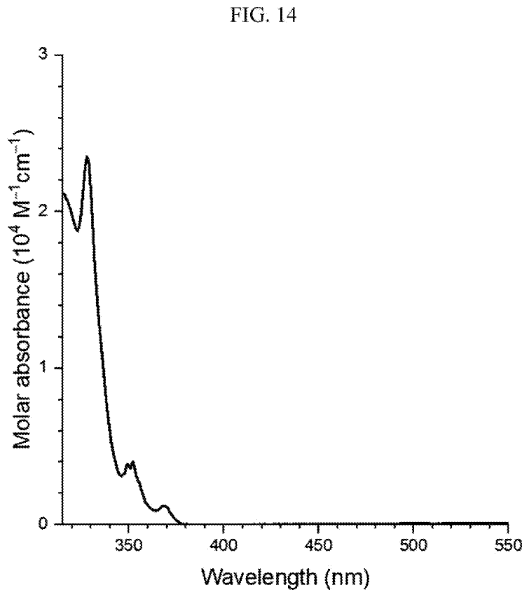

UV-Vis absorption spectra were collected on Agilent, Cary-300 spectrometer at 298 K. Sample solutions for measurements were prepared by dissolving the Au(I) complexes according to the Examples in toluene at a concentration of 10 μM prior to measurement. Each sample solution was delivered into a quartz cell (Hellma, beam path length=1.0 cm) for measuring UV-Vis absorption spectrum. UV-Vis absorption spectra of the Au(I) complexes according to Examples 1 to 12 are shown in FIG. 3 to FIG. 14, respectively, and absorption peak wavelength (Aabs) of each spectrum is described in Table 1.

### (2) Steady-State Photoluminescence

Photoluminescence spectra were collected on PTI, Quanta Master 400 scanning spectrofluorometer, or Varian, Cary Eclipse fluorescence spectrophotometer. Photoluminescence was measured for the films coated on 2 cm×2 cm quartz plates by using solutions containing toluene, 5 wt % of Zeonex (for Examples 1, 7, 8, and 10 to 12) or polymethyl(meth)acrylate (PMMA) (for Examples 2 to 6, and 9), and each of Au(I) complexes according to Examples 1 to 12 (5 wt % relative to Zeonex or PMMA) with an EPLEX, SPIN-1200D spin coater. The solutions were passed through poly(tetrafluoroethylene) syringe filters (pore size=0.45 μm) before coating.

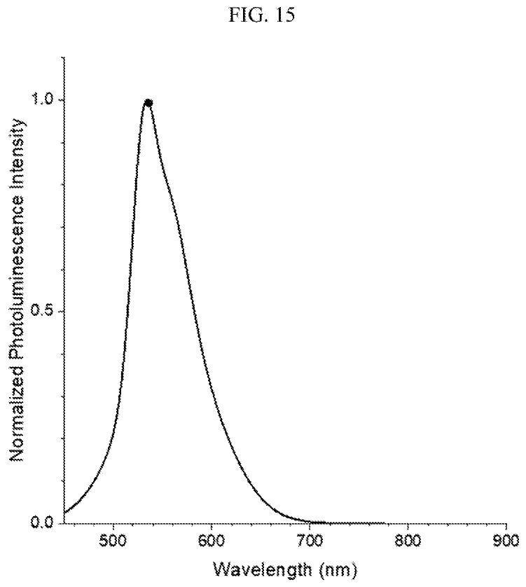

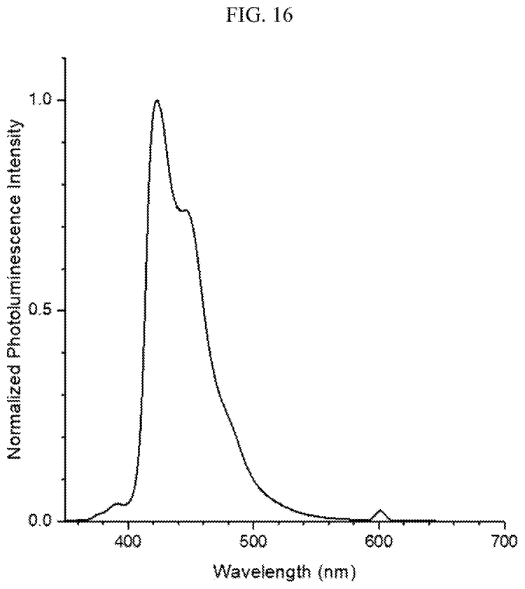

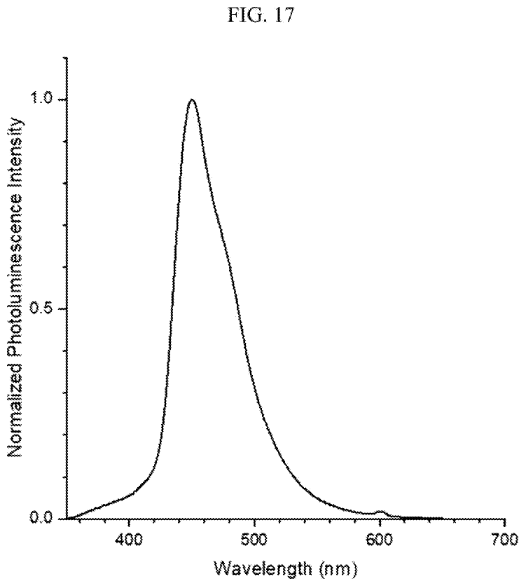

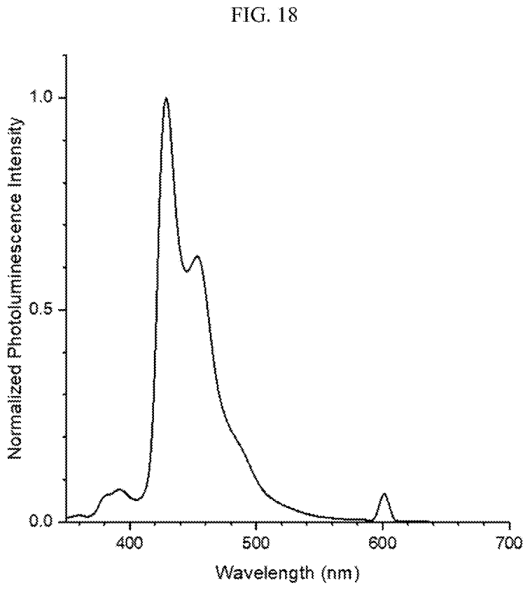

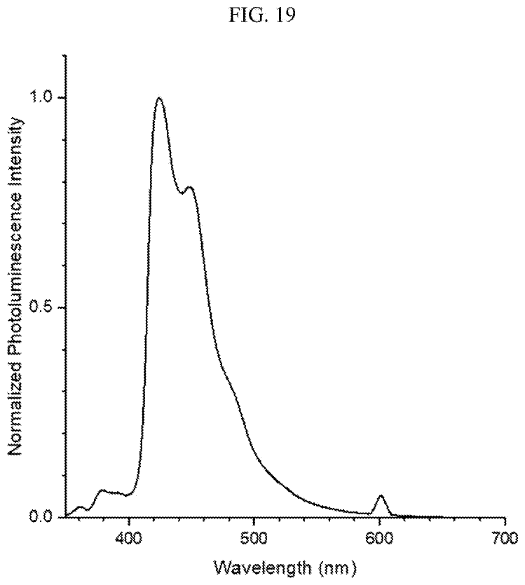

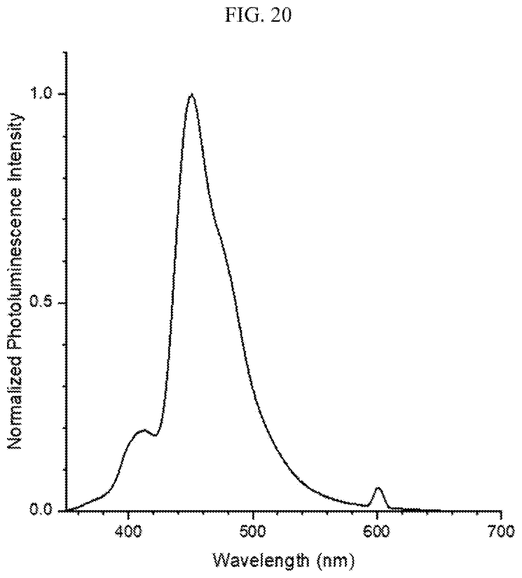

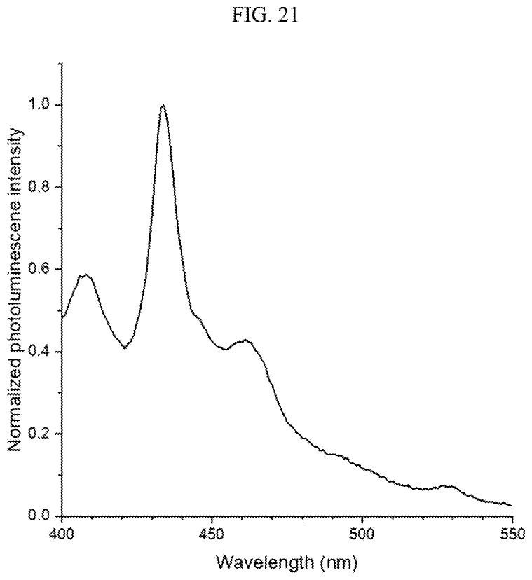

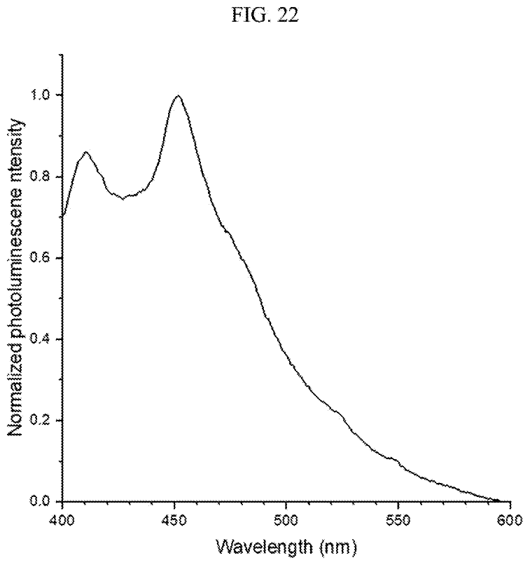

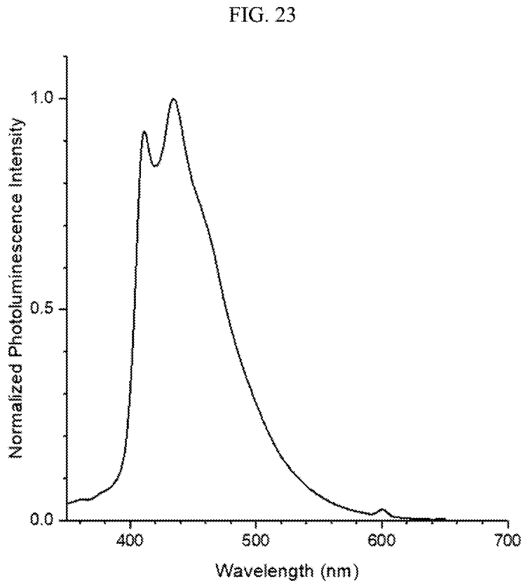

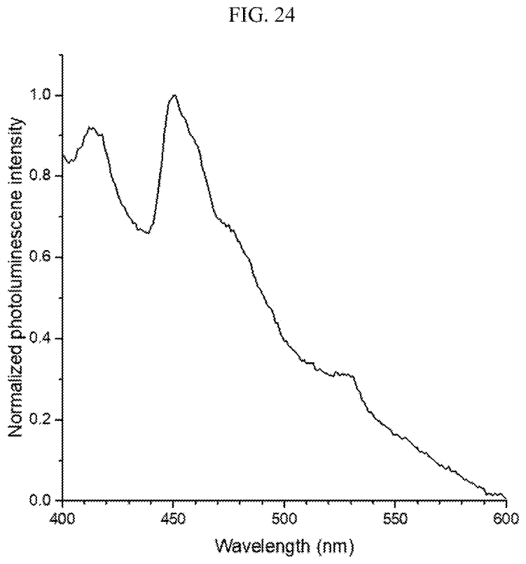

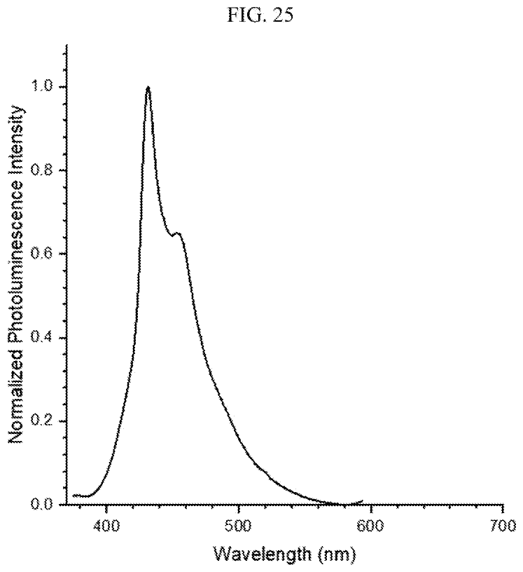

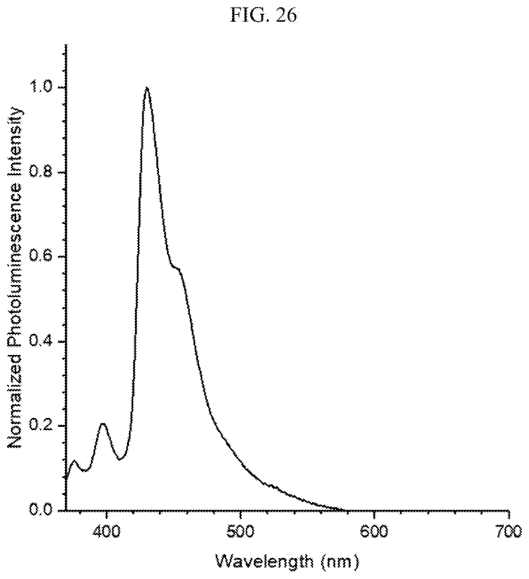

Photoluminescence spectra of each sample according to Examples 1 to 12 are shown in FIG. 15 to FIG. 26, respectively, and photoluminescent peak wavelength (λₑₘ) of each spectrum is described in Table 1.

### (3) Determination of Absolute Photoluminescence Quantum Yields

Photoluminescence quantum yields (ϕ_{PL}) of the films used for measuring the steady-state photoluminescence were determined absolutely, using the methods embedded on PTI, Quanta Master 400 scanning spectrofluorometer, and FelixGX software. The photon flux of an excitation beam (Iₑₓ (0)) was quantified in the absence of a sample. Sample was placed in the integrating sphere (PTI), and an excitation beam was focused at the center of the sample. Then, the flux of the excitation photons (Iₑₓ (s)) was quantitated. Finally, the photon flux of the photoluminescence emission from the sample (Iₑₘ) was measured under the following conditions: integration time, 0.1 second (s); step size, 0.0625 nm; emission range, 410 nm to 900 nm. The ratio of the emission photon flux (Iₑₘ) to the absorbed photon flux (Iₑₓ(0)/Iₑₓ(s)) corresponds to the photoluminescence quantum yields (ϕ_{PL}). That is, ϕ_{PL}=Iₑₘ/(Iₑₓ(0)/Iₑₓ(s)). The measurement was repeated in triplicate for each fresh sample.

### (4) Photoluminescence Lifetime

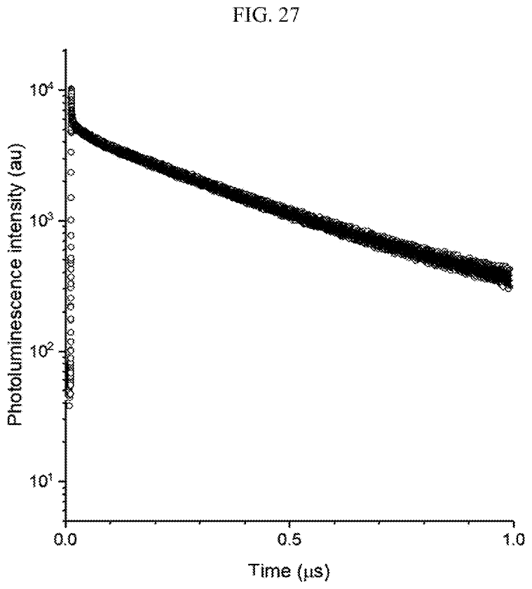

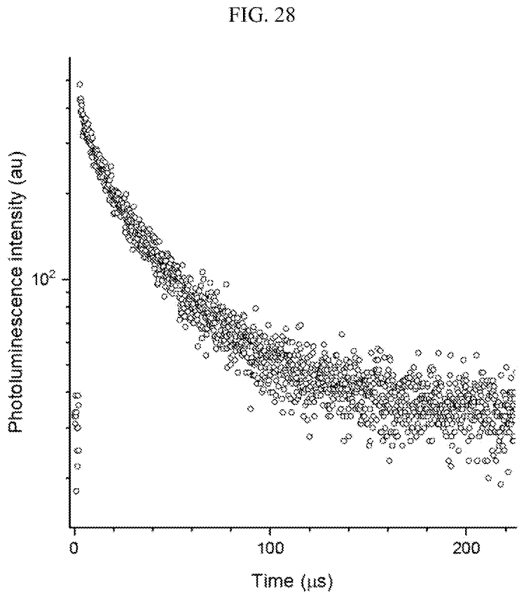

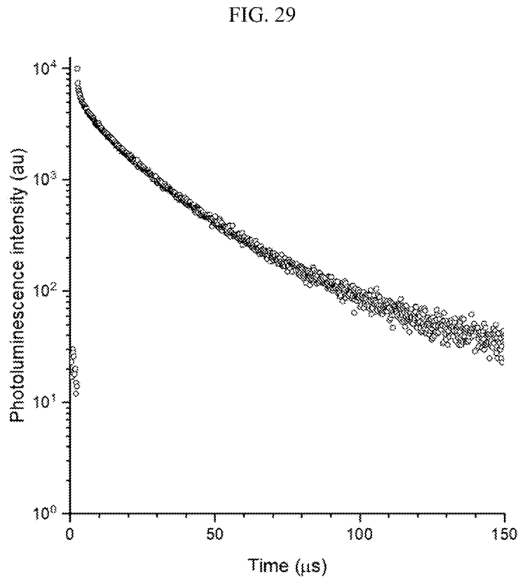

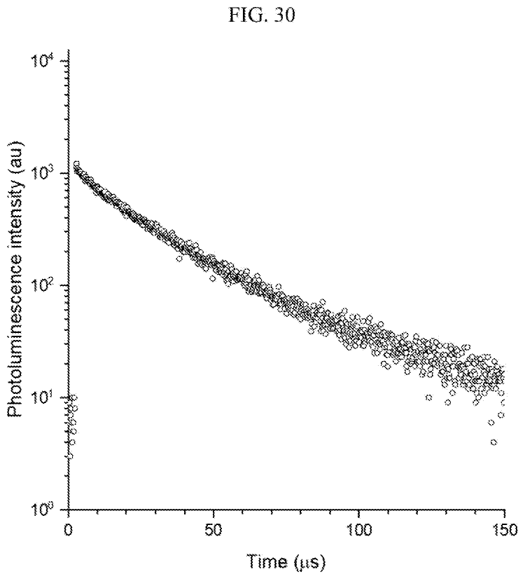

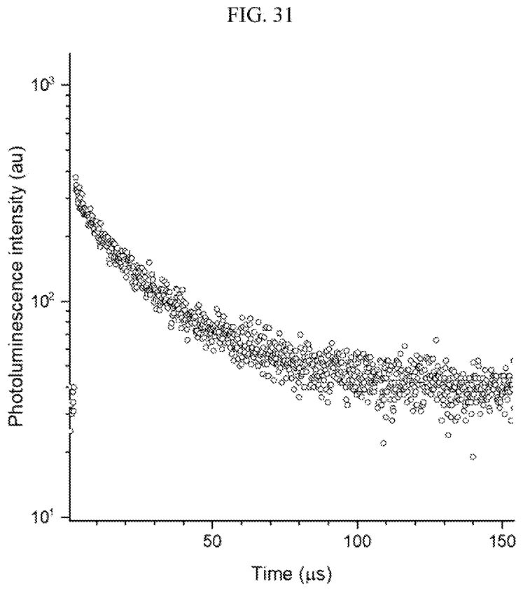

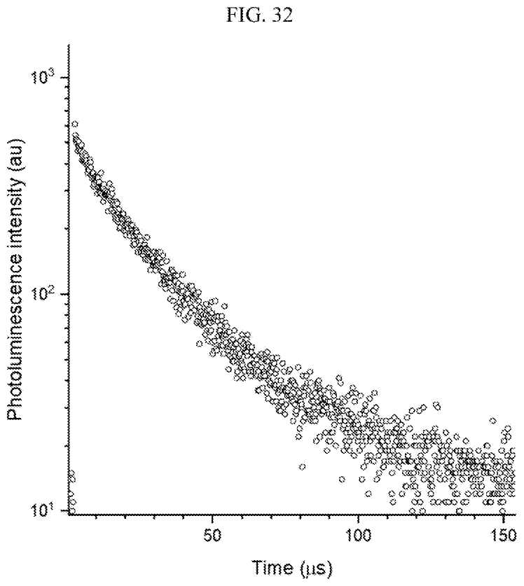

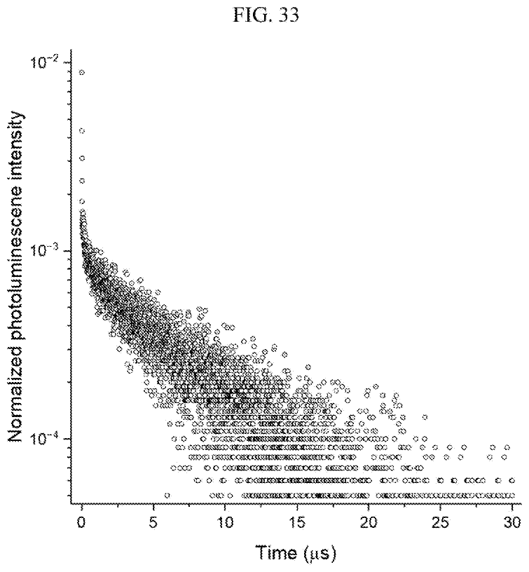

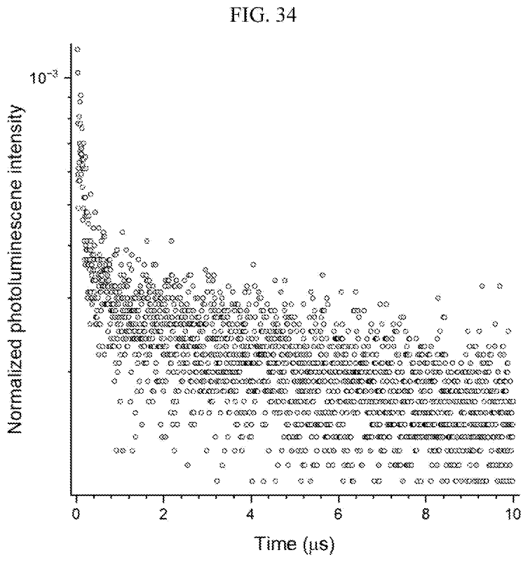

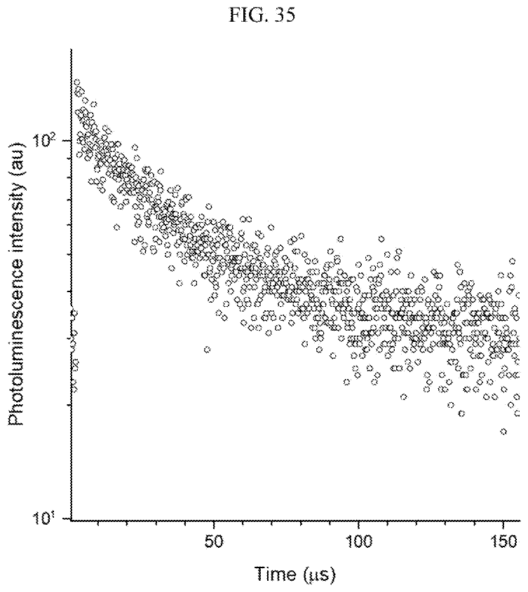

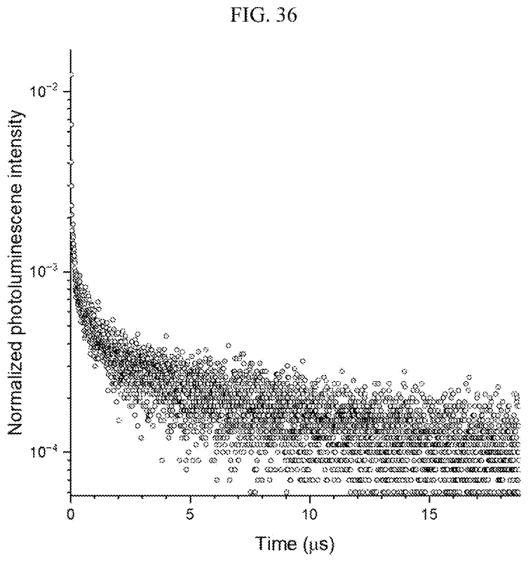

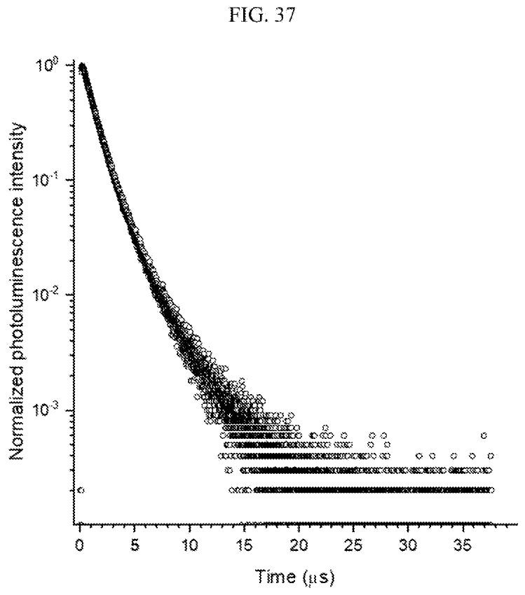

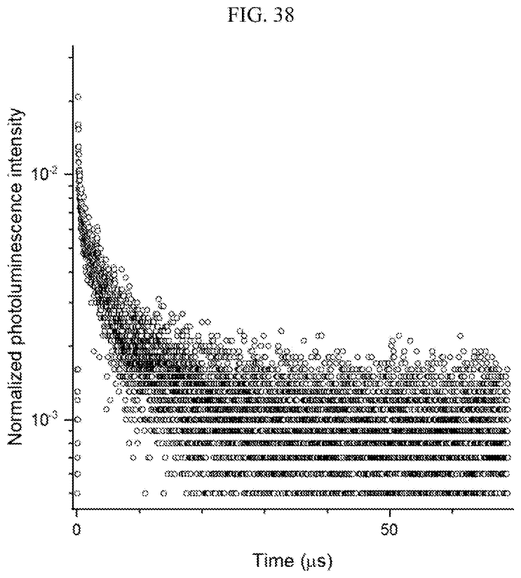

Transient Photoluminescence and photoluminescence lifetime were collected by employing time-correlated single-photon-counting (TCSPC) technique using a PicoQuant, FluoTime 200 instrument through a motorized monochromator at the peak emission wavelength of each sample. An LED or a diode laser that produce 345 nm or 377 nm pulses (PicoQuant, LDH375) was driven by a PDL800-D driver (PicoQuant). The weighted average photoluminescence lifetime (T_{obs}) was measured through multi-exponential model fitting of the time-resolved luminescence lifetime decay profiles monitored after pulse application of the laser. The time-resolved luminescence decay profiles were fitted to the triexponential decay model built into OriginLab, OriginPro 2022b software. Transient Photoluminescence results of the samples according to Examples 1 to 12 are shown in FIG. 27 to FIG. 38, respectively, and the weighted average photoluminescence lifetimes (T_{obs}) are described in Table 1.

### (5) Determination of Radiative and Nonradiative Rate Constants

The radiative rate constant kᵣ and the nonradiative rate constant kₙᵣ for light emission can each be calculated by the following equations:

$${k}_{r} = {Φ}_{PL} / {T}_{obs} \\ {k}_{nr} = ( 1 - {Φ}_{PL} ) / {T}_{obs}$$

In the above equations, ϕ_{PL} is the photoluminescence quantum yield, and T_{obs} is the weighted average photoluminescence lifetime of each sample that are measured as described above.

The steady-state UV-Vis absorption peak wavelength (λ_{abs}), the steady-state photoluminescence peak wavelength (λₑₘ), the weighted average photoluminescence lifetime (T_{obs}), the photoluminescence quantum yield (ϕ_{PL}), and the radiative rate constant (kᵣ) and non-radiative rate constant (kₙᵣ) for light emission are shown in Table 1 below.

TABLE 1

| | λ_{abs} | λₑₘ | T_{obs} | | kᵣ | kₙᵣ |
|---|---|---|---|---|---|---|
| | (nm) | (nm) | (μs) | Φ_{PL} | (s⁻¹) | (s⁻¹) |
| Example 1 | 462 | 533 | 0.32 | 0.84 | 2.6 × 10⁶ | 5.0 × 10⁵ |
| Example 2 | 366 | 423 | 31 | 0.06 | 1.9 × 10³ | 1.4 × 10⁵ |
| Example 3 | 344 | 450 | 19 | 0.05 | 2.5 × 10³ | 3.8 × 10⁴ |
| Example 4 | 377 | 429 | 25 | 0.03 | 1.1 × 10³ | 3.8 × 10⁴ |
| Example 5 | 369 | 424 | 25 | 0.02 | 0.8 × 10³ | 3.8 × 10⁴ |
| Example 6 | 342 | 451 | 22 | 0.03 | 1.2 × 10³ | 3.7 × 10⁴ |
| Example 7 | 364 | 435 | 4.8 | 0.03 | 6.3 × 10³ | 2.0 × 10⁵ |
| Example 8 | 371 | 452 | 0.88 | 0.03 | 3.4 × 10⁴ | 1.1 × 10⁶ |
| Example 9 | 354 | 435 | 36 | 0.02 | 0.5 × 10³ | 5.0 × 10⁴ |
| Example 10 | 366 | 450 | 6.8 | N.D. | N.D. | N.D. |
| Example 11 | 350 | 432 | 7.4 | 0.06 | 8.1 × 10³ | 1.3 × 10⁵ |
| Example 12 | 350 | 425 | 5.0 | 0.07 | 1.4 × 10⁴ | 1.9 × 10⁵ |

(N.D.: not determined)

As shown in Table 1, the compounds according to an embodiment have absorption peak wavelengths in a range of about 500 nm or less and exhibit luminescent properties that emit light having longer wavelengths than those absorbed. The compound according to an embodiment may exhibit various luminescent properties depending on the structure of the carbene ligand and/or amido ligand, and the type of substituent bonded to the ligand. Therefore, by changing the structure of the ligand and/or type of the substituent, compounds that exhibit luminescent properties at various wavelengths may be prepared.

### 3. Fabrication and Characterization of OILED

A multilayered OLED is constructed with the following configuration: 50 nm of indium tin oxide (ITO)/60 nm of poly(3,4-ethlyenedioxythiophene):polystyrenesulfonate (PEDOT:PSS)/20 nm of 4,4′-cyclohexylidenebis[N,N-bis(4-methylphenyl)aniline] (TAPC)/10 nm of 9,9-dimethyl-10-(9-phenyl-9H-carbazol-3-yl)-9,10-dihydroacridine (PCZAC)/emitting layer (25 nm)/5 nm of diphenyl-4-triphenylsilylphenyl-phosphineoxide (TSPO1)/40 nm of 2,2′,2″-(1,3,5-benzinetriyl)-tris(1-phenyl-1H-benzimidazole) (TPBi)/LiF (1.5 nm)/Al (200 nm).

The emitting layer involved a mixed host system of 2-phenyl-4,6-bis(12-phenylindolo[2,3-a]carbazole-11-yl)-1,3,5-triazine (PBICT) and 4-(3-(triphenylene-2-yl)phenyl)dibenzo[b,d]thiophene (DBTTP1) at a weight ratio of 7:3. Au(I) complexes were co-evaporated with the hosts at doping concentrations of 1 wt % to 10 wt %. ITO served as the anode, PEDOT:PSS was used as a hole-injection layer, TAPC was used as a hole-transporting layer, PCZAC was used as an electron-blocking layer, PBICT was used as a TADF host, DBTTP1 was used as a triplet-exciton-guiding host, TSPO1 was used as a hole-blocking layer, TPBi was used as an electron-transporting layer, LiF was used as an electron-injection layer, and Al served as a cathode. All devices were fabricated by thermal evaporation under 5×10⁻⁷ torr. Encapsulation was subsequently conducted under a nitrogen atmosphere to prevent the degradation of the device. Characteristics of the devices were measured using a Keithley, 2400 source meter and a Konica Minolta, CS2000 spectroradiometer.

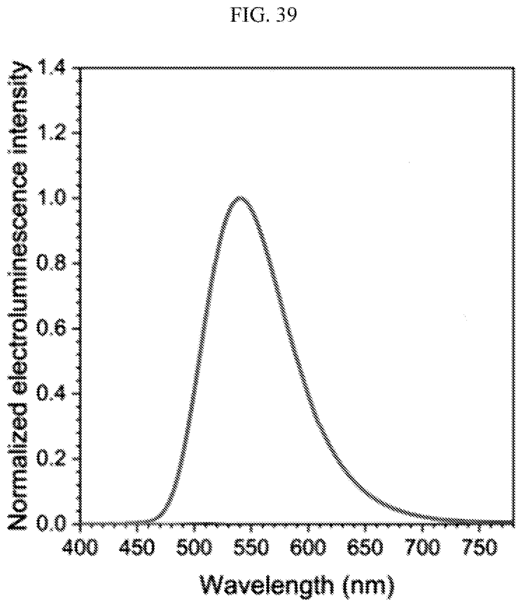

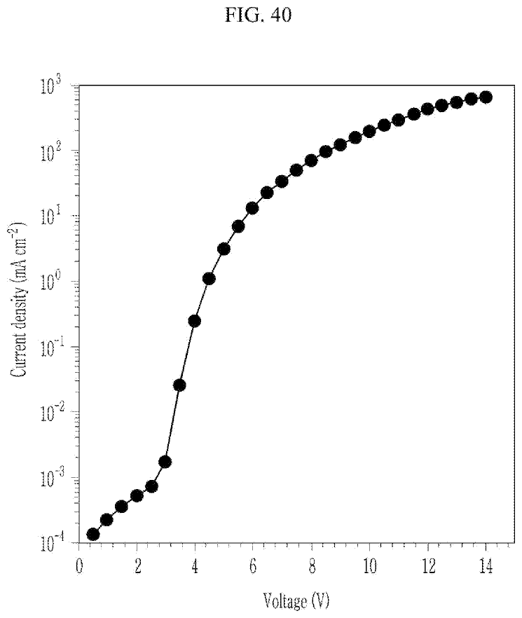

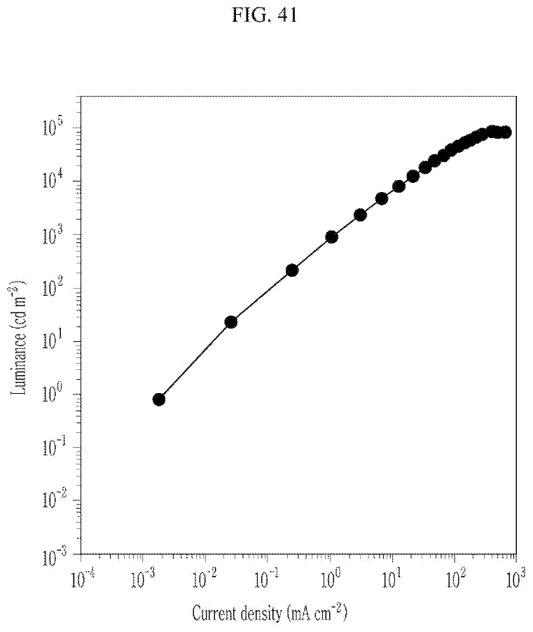

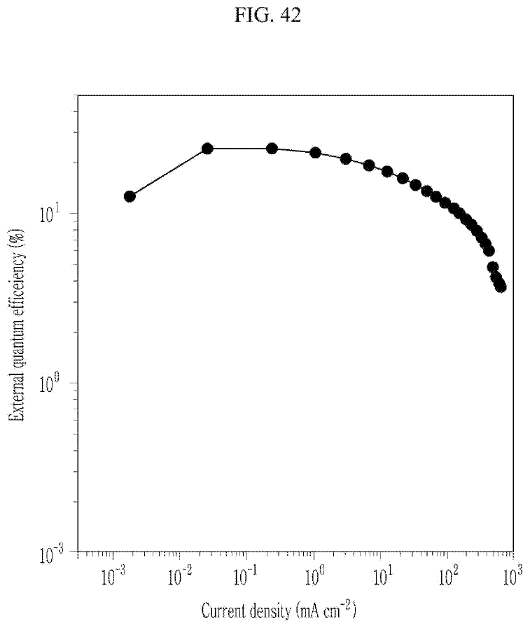

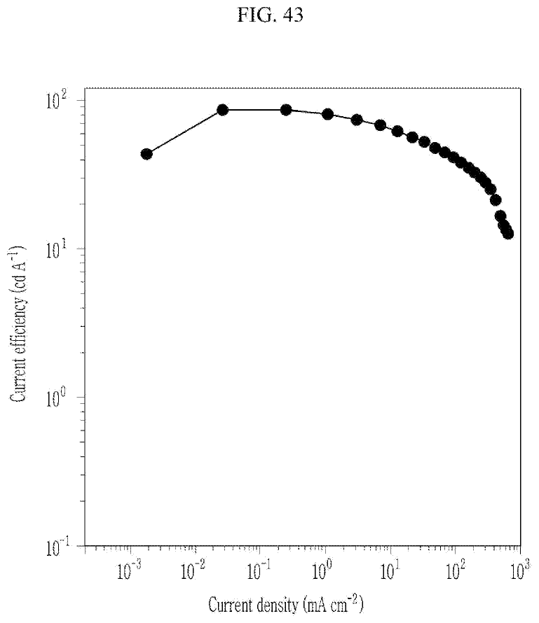

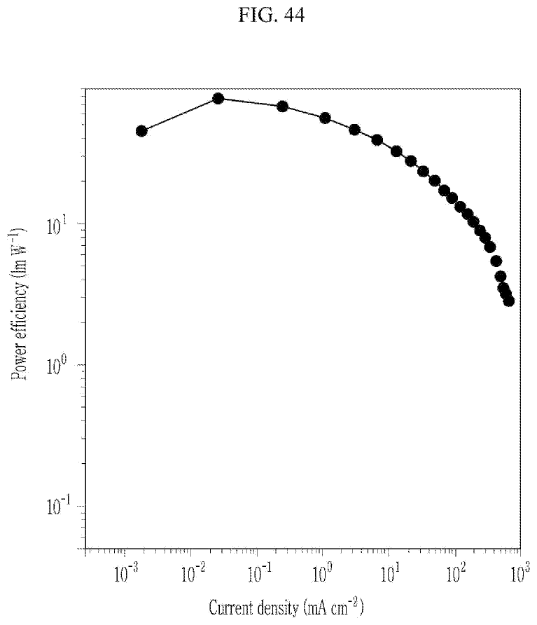

Electroluminescence spectrum, current density versus voltage, luminance versus current density, external quantum efficiency (EQE) versus current density, current efficiency versus current density, and power efficiency versus current density of the OLED produced above and containing 3% by weight of [Au(^{Dipp}PZI)(ACD)] according to Example 1 as a gold (Au(I)) complex in the emitting layer are measured, and the results are shown in FIG. 39 to FIG. 44.

Although the embodiments have been described in detail above, the scope of rights is not limited thereto, and various modifications and improvements made by those skilled in the art using the basic concepts defined in the following claims also fall within the scope of rights.

What is claimed is:

1. A compound represented by Chemical Formula 1: 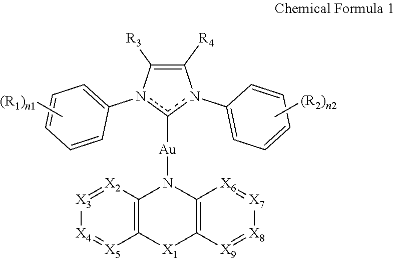
wherein in Chemical Formula 1,
R₁ and R₂ are, each independently, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, a substituted or unsubstituted C2 to C30 heterocyclic group, a substituted or unsubstituted C1 to C30 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, or a substituted or unsubstituted C2 to C30 heterocyclic group), a nitro group, a halogen atom, or a combination thereof,
n1 and n2 are, each independently, an integer of 0 to 5,
R₃ and R₄ are, each independently, hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, a substituted or unsubstituted C2 to C30 heterocyclic group, a substituted or unsubstituted C1 to C30 alkoxy group, a substituted or unsubstituted amino group, a substituted or unsubstituted silyl group, a cyano group, a carboxyl group, —C(═O)R^{a}(wherein, R^{a} is hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, or a substituted or unsubstituted C2 to C30 heterocyclic group), a nitro group, a halogen atom, or a combination thereof, or optionally, the groups of R₃ and R₄ are linked to each other to form a ring,
X₁ is single bond, —(CRR′)ₙ₃—, —C(R)═C(R′)—, —C≡C—, —C(═O)—, —O—, —S—, S(═O)—, —S(═O)₂—, —NR—, or a combination thereof, wherein, R and R′ are, each independently, hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, a substituted or unsubstituted C2 to C30 heterocyclic group, a substituted or unsubstituted C1 to C30 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, or a substituted or unsubstituted C2 to C30 heterocyclic group), a nitro group, a halogen atom, or a combination thereof, wherein n3 is an integer of 1 to 5, and
X₂ to X₉ are, each independently, —CR″— or N, wherein, R″ is hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, a substituted or unsubstituted C2 to C30 heterocyclic group, a substituted or unsubstituted C1 to C30 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, or a substituted or unsubstituted C2 to C30 heterocyclic group), a nitro group, a halogen atom, or a combination thereof.

2. The compound according to claim 1, wherein R₁ and R₂ are, each independently, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, a substituted or unsubstituted C2 to C20 heterocyclic group, a substituted or unsubstituted C1 to C20 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, or a substituted or unsubstituted C2 to C20 heterocyclic group), a nitro group, a halogen atom, or a combination thereof.

3. The compound according to claim 1, wherein R₃ and R₄ are, each independently, hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, a substituted or unsubstituted C2 to C20 heterocyclic group, a substituted or unsubstituted C1 to C20 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, or a substituted or unsubstituted C2 to C20 heterocyclic group), a nitro group, a halogen atom, or a combination thereof, or optionally, the groups of R₃ and R₄ are linked to each other to form an aromatic or heteroaromatic ring.

4. The compound according to claim 1, wherein X₁ is single bond, —(CRR′)ₙ₃—, —C(R)═C(R′)—, —C≡C—, —C(═O)—, —O—, —S—, S(═O)—, —S(═O)₂—, —NR—, or a combination thereof, wherein, R and R′ are, each independently, hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, a substituted or unsubstituted C2 to C20 heterocyclic group, a substituted or unsubstituted C1 to C20 alkoxy group, a substituted or unsubstituted amino group, a substituted or unsubstituted silyl group, a cyano group, a carboxyl group, —C(═O)R^{a}(wherein, R^{a} is hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, or a substituted or unsubstituted C2 to C20 heterocyclic group), a nitro group, a halogen atom, or a combination thereof, wherein n3 is an integer of 1 to 3.

5. The compound according to claim 1, wherein X₂ to X₉ are, each independently, —CR″— or N, wherein, R″ is hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, a substituted or unsubstituted C2 to C20 heterocyclic group, a substituted or unsubstituted C1 to C20 alkoxy group, a substituted or unsubstituted amino group, a substituted or unsubstituted silyl group, a cyano group, a carboxyl group, —C(═O)R^{a}(wherein, R^{a} is hydrogen, deuterium, a substituted or unsubstituted C1 to C20 saturated or unsaturated aliphatic hydrocarbon group, a substituted or unsubstituted C3 to C20 saturated or unsaturated alicyclic hydrocarbon group, a substituted or unsubstituted C6 to C20 aromatic hydrocarbon group, or a substituted or unsubstituted C2 to C20 heterocyclic group), a nitro group, a halogen atom, or a combination thereof.

6. The compound according to claim 1, wherein X₁ is single bond, and X₂ to X₉ are, each independently, —CR″— or N, wherein, R″ is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a}(wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof.

7. The compound according to claim 1, wherein X₁ is single bond, and one of X₂ to X₉ is N, and the others of X₂ to X₉ are, each independently, —CR″, wherein, R″ is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof.

8. The compound according to claim 1, wherein X₁ is —(CRR′)ₙ₃—, —C(═O)—, —O—, —S—, S(═O)—, —S(═O)₂—, —NR—, or a combination thereof, wherein, R and R′ are, each independently, hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof, wherein n3 is an integer of 1 or 2, and
X₂ to X₉ are, each independently, —CR″— or N, wherein, R″ is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof.

9. The compound according to claim 8, wherein X₂ to X₉ are, each independently, —CR″—, wherein, R″ is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a}(wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof.

10. The compound according to claim 1, wherein R₁ and R₂ are, each independently, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C1 to C10 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof,
n1 and n2 are, each independently, an integer of 1 to 3,
R₃ and R₄ are, each independently, hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a}(wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof, or optionally, the groups of R₃ and R₄ are linked to each other to form an aromatic or heteroaromatic ring,
X₁ is single bond, —(CRR′)ₙ₃—, —C(R)═C(R′)—, —C≡C—, —C(═O)—, —O—, —S—, S(═O)—, —S(═O)₂—, —NR—, or a combination thereof, wherein, R and R′ are, each independently, hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof, wherein n3 is an integer of 1 to 3, and
X₂ to X₉ are, each independently, —CR″— or N, wherein, R″ is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, or a substituted or unsubstituted C2 to C10 heterocyclic group), a nitro group, a halogen atom, or a combination thereof.

11. The compound according to claim 1, wherein R₁ and R₂ are, each independently, a substituted or unsubstituted C1 to C10 saturated or unsaturated aliphatic hydrocarbon group, a substituted or unsubstituted C3 to C10 saturated or unsaturated alicyclic hydrocarbon group, or a combination thereof,
n1 and n2 are, each independently, an integer of 2,
R₃ and R₄ are, each independently, hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a cyano group, a carboxyl group, a substituted or unsubstituted C1 to C10 alkanoyl group, an aldehyde group, or a combination thereof, or optionally, the groups of R₃ and R₄ are linked to each other to form an aromatic or heteroaromatic ring,
X₁ is single bond, —(CRR′)ₙ₃—, —C(═O)—, —O—, —S—, S(═O)—, —S(═O)₂—, —NR—, or a combination thereof, wherein, R and R′ are, each independently, hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a substituted or unsubstituted silyl group, a cyano group, a carboxyl group, a substituted or unsubstituted C1 to C10 alkanoyl group, an aldehyde group, a nitro group, a halogen atom, or a combination thereof, wherein n3 is an integer of 1 to 3, provided that,
if X₁ is single bond, then, (i) one of X₂ to X₉ is N, and the others of X₂ to X₉ are, each independently, —CR″, or (ii) X₂ to X₉ are, each independently, —CR″, and
if X₁ is —C(═O)—, then, X₂ to X₉ are, each independently, —CR″,
wherein, R″ is be hydrogen, deuterium, a substituted or unsubstituted C1 to C10 saturated or unsaturated aliphatic hydrocarbon group, a substituted or unsubstituted C3 to C10 saturated or unsaturated alicyclic hydrocarbon group, a substituted or unsubstituted C6 to C10 aromatic hydrocarbon group, a substituted or unsubstituted C2 to C12 heterocyclic group, a substituted or unsubstituted C1 to C10 alkoxy group, a substituted or unsubstituted amino group, a cyano group, a carboxyl group, a substituted or unsubstituted C1 to C10 alkanoyl group, an aldehyde group, a nitro group, a halogen atom, or a combination thereof.

12. The compound according to claim 1, wherein R₁ and R₂ are, each independently, an unsubstituted C1 to C10 alkyl group,
n1 and n2 are, each independently, an integer of 2,
R₃ and R₄ are, each independently, hydrogen, deuterium, a substituted or unsubstituted C1 to C10 alkyl group, a substituted or unsubstituted C6 to C10 aryl group, a substituted or unsubstituted C2 to C12 heterocyclic group, a substituted or unsubstituted amino group, a cyano group, or a combination thereof, or optionally, the groups of R₃ and R₄ are linked to each other to form an aromatic or heteroaromatic ring,
X₁ is single bond, —(CRR′)ₙ₃—, —C(═O)—, —O—, —S—, S(═O)—, —S(═O)₂—, —NR—, or a combination thereof, wherein, R and R′ are, each independently, hydrogen, deuterium, a substituted or unsubstituted C1 to C10 alkyl group, a substituted or unsubstituted C3 to C10 cycloalkyl group, a substituted or unsubstituted C6 to C10 aryl group, a substituted or unsubstituted C1 to C10 alkoxy group, a substituted or unsubstituted amino group, a cyano group, a halogen atom, or a combination thereof, wherein n3 is an integer of 1 or 2, provided that,
if X₁ is single bond, then, (i) one of X₂ to X₉ is N, and the others of X₂ to X₉ are, each independently, —CR″, or (ii) X₂ to X₉ are, each independently, —CR″, and
if X₁ is —(CRR′)ₙ₃—, —C(═O)—, —O—, —S—, S(═O)—, —S(═O)₂—, or —NR—, then, X₂ to X₉ are, each independently, —CR″,
wherein, R″ is hydrogen, deuterium, a substituted or unsubstituted C1 to C10 alkyl group, a substituted or unsubstituted C3 to C10 cycloalkyl group, a substituted or unsubstituted C6 to C10 aryl group, a substituted or unsubstituted C2 to C12 heterocyclic group, a cyano group, or a combination thereof.

13. The compound according to claim 1, wherein Chemical Formula 1 is represented by Chemical Formula 2 or Chemical Formula 3: 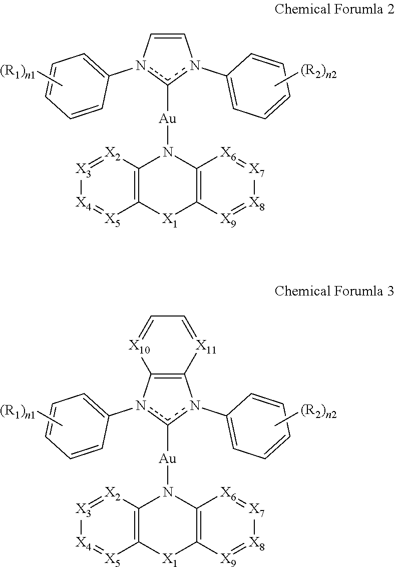
wherein in Chemical Formula 2 and Chemical Formula 3,
R₁ and R₂, n1 and n2, and X₁ to X₉ are the same as defined in Chemical Formula 1, and
wherein in Chemical Formula 3,
X₁₀ and X₁₁ are, each independently, —CR′″— or N, wherein, R′″ is hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, a substituted or unsubstituted C2 to C30 heterocyclic group, a substituted or unsubstituted C1 to C30 alkoxy group, a substituted or unsubstituted amino group, a substituted or unsubstituted silyl group, a cyano group, a carboxyl group, —C(═O)R^{a} (wherein, R^{a} is hydrogen, deuterium, a substituted or unsubstituted C1 to C30 saturated or unsaturated aliphatic hydrocarbon group, a substituted or unsubstituted C3 to C30 saturated or unsaturated alicyclic hydrocarbon group, a substituted or unsubstituted C6 to C30 aromatic hydrocarbon group, or a substituted or unsubstituted C2 to C30 heterocyclic group), a nitro group, a halogen atom, a combination thereof.

14. The compound according to claim 1, comprising any one represented in Group 1:

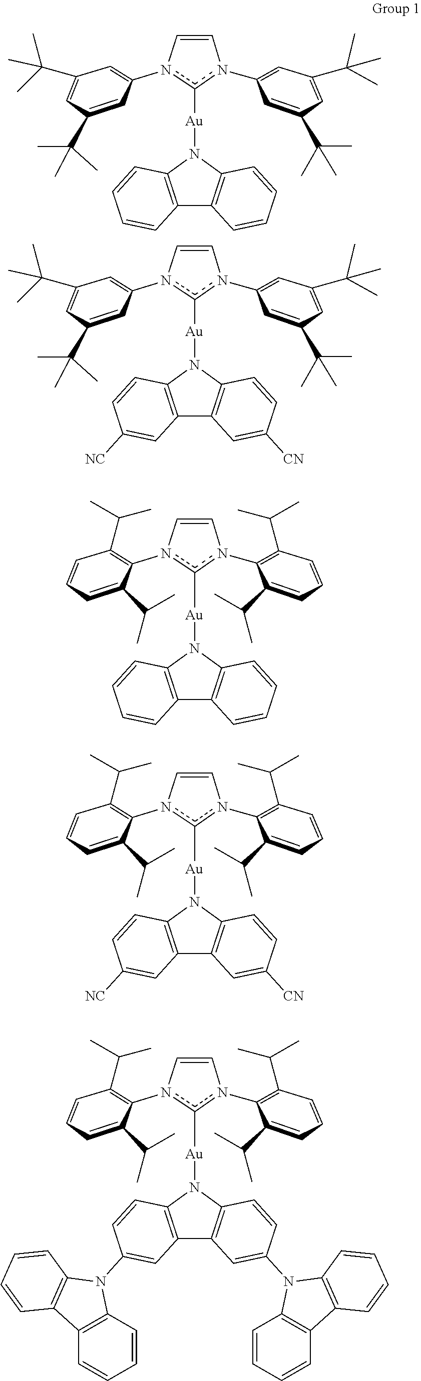

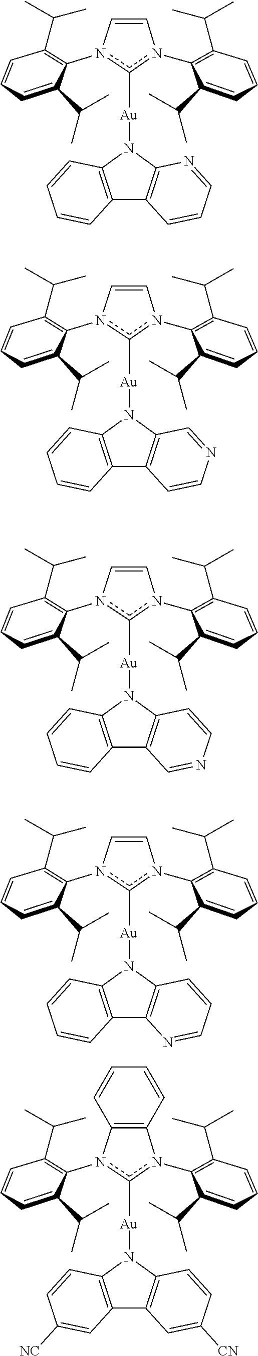

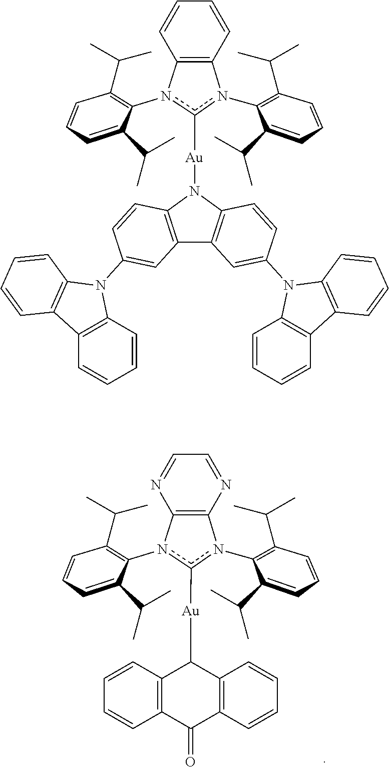

15. An organic electronic component comprising the compound of claim 1.

16. The organic electronic component according to claim 15, comprising an organic light-emitting diode (OLED) or a light-emitting electrochemical cell (LEEC).

17. The organic electronic component according to claim 15, comprising an anode and a cathode facing each other, and a light-emitting layer disposed between the anode and the cathode, wherein the compound is included in the light-emitting layer.

18. A light-emitting layer comprising the compound according to claim 1.

19. An organic light-emitting diode (OLED) comprising the light-emitting layer according to claim 18.

20. A device comprising the OLED according to claim 19.
